(19) United States
(12) Patent Application Publication
(10) Pub. No.: US 2009/0291512 A1
(43) Pub. Date: Nov. 26, 2009

(54) SEMICONDUCTOR DEVICE PATTERN VERIFICATION METHOD, SEMICONDUCTOR DEVICE PATTERN VERIFICATION PROGRAM, AND SEMICONDUCTOR DEVICE MANUFACTURING METHOD

(76) Inventors: Kyoko IZUHA, Atsugi-shi (JP); Satoshi TANAKA, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/470,289

(22) Filed: May 21, 2009

(30) Foreign Application Priority Data
May 22, 2008 (JP) 2008-134579

(51) Int. Cl. H01L 21/66; G06F 17/50

(52) U.S. Cl. 438/16; 716/21; 257/E21.53

(57) ABSTRACT

Information on a transfer pattern created from a design pattern corresponding to a pattern to be formed on a substrate is acquired as pattern transfer information. The design pattern is compared with the transfer pattern and, on the basis of the feature quantity obtained from the comparison, the pattern transfer information and the design pattern are classified. A threshold value is set for the feature quantity and, on the basis of the threshold value, the pattern transfer information and the design pattern are further classified. Then, verification is conducted to see if the transfer pattern satisfies the threshold value.

### CROSS-REFERENCE TO RELATED APPLICATIONS

This application is based upon and claims the benefit of priority from prior Japanese Patent Application No. 2008-134579, filed May 22, 2008, the entire contents of which are incorporated herein by reference.

### BACKGROUND OF THE INVENTION

1. Field of the Invention

This invention relates to a lithographic technique for manufacturing a semiconductor device which includes semiconductor elements and liquid-crystal display elements, and more particularly to a pattern verification method, a pattern verification program, and a semiconductor device manufacturing method which are capable of forming microscopic patterns efficiently and with high accuracy.

2. Description of the Related Art

In recent years, semiconductor device manufacturing technology has made remarkable progress and semiconductor devices whose minimum processing dimensions are 0.1 μm or less have been mass-produced. However, as the patterns have been miniaturized further, it has been getting more difficult to form the patterns faithfully, causing the problem of preventing the final finished dimensions from following the design pattern. It has been known that, in the lithographic process and etching process, which are the most important in achieving microscopic processes, the layout environment of other patterns arranged around a pattern to be formed has a significant effect on the dimensional accuracy of the pattern to be formed. Correction techniques, including Optical Proximity Correction (OPC) and Process Proximity Correction (PPC) have been disclosed as techniques for reducing such an effect in, for example, Jpn. Pat. Appln. KOKAI Publication No. 9-319067 and in D. M. Newmark, et al., “Large Area Optical Proximity Correction using Pattern Based Correction,” SPIE Vol. 2322, 1994, 374.

Recently, the element pattern and wiring pattern of a cell have been laid out (designed) from the viewpoint of, for example, performance so as to satisfy a timing margin for the time when an STA (Statistical Timing Analysis) circuit or the like operates properly. Accordingly, for example, the following problem has been becoming more serious. Specifically, to keep the operating speed of the transistor within the timing margin, cells whose drive power is low have to be used. The insertion of a buffer or the like results in an increase in the chip area. Since timing closure is performed using transistors designed with dimensions under worst conditions, the number of iterations increases.

Moreover, from the viewpoint of lithographic processes, for example, the following problem has been becoming more serious. As the correction techniques, including optical proximity correction (OPC) and process proximity correction (PPC), are getting more complex, the design pattern created by the designer differs greatly from the mask pattern used in exposure. Accordingly, a finished pattern shape on the wafer cannot be predicted easily and therefore it is essential to verify the finished pattern shape using a process simulator before shipment of the design pattern. However, since lithographic verification of the design pattern is performed in the final stage of the design process, the feedback of the verification result leads to virtually turning back to the design process, which makes TAT (Turn Around Time) longer. That is, the following problem arises: a load is doubly imposed on the lithographic process before and after the artwork.

To solve such a problem, for example, Jpn. Pat. Appln. KOKAI Publication No. 2006-318978 has disclosed a pattern design method aimed at solving the problem of a trade-off between an OPC process performed on the manufacture side, its verification, and timing optimization performed on the design side. In addition, Jpn. Pat. Appln. KOKAI Publication No. 2006-126745 has disclosed a pattern design method of modifying a design pattern according to the vertex density of the pattern. Moreover, Jpn. Pat. Appln. KOKAI Publication No. 2003-162041 has disclosed a pattern design method of partially modifying a pattern which will possibly become a problem in the artwork stage after pattern design. Specifically, first, all of the patterns which will possibly become problems in the artwork stage are registered in a library beforehand. Then, the problem pattern is matched with the design pattern. Then, of the problem patterns, a site which will possibly become a problem detected by matching is partially modified.

However, as patterns have been getting more microscopic and complex, a problem has begun to arise which cannot be dealt with even by the methods disclosed in, for example, Jpn. Pat. Appln. KOKAI Publication No. 2006-126745 and Jpn. Pat. Appln. KOKAI Publication No. 2003-162041. Specifically, the method disclosed in Jpn. Pat. Appln. KOKAI Publication No. 2006-126745 has the following problem: information on the vertex density of a pattern is insufficient in accuracy. The method disclosed in Jpn. Pat. Appln. KOKAI Publication No. 2003-162041 has the problem of increasing TAT if a modification is made in the artwork stage.

### BRIEF SUMMARY OF THE INVENTION

According to a first aspect of the invention, there is provided a pattern verification method comprising: acquiring information on a transfer pattern created from a design pattern corresponding to a pattern to be formed on a substrate as pattern transfer information; comparing the design pattern with the transfer pattern; classifying the pattern transfer information and the design pattern on the basis of the feature quantity obtained from the comparison; setting a threshold value for the feature quantity; further classifying on the basis of the threshold value the pattern transfer information and the design pattern classified on the basis of the feature quantity; and verifying whether the transfer pattern satisfies the threshold value.

According to a second aspect of the invention, there is provided a computer-readable medium with a pattern verification program which causes a computer to acquire information on a transfer pattern created from a design pattern corresponding to a pattern to be formed on a substrate as pattern transfer information; to compare the design pattern with the transfer pattern; to classify the pattern transfer information and the design pattern on the basis of the feature quantity obtained from the comparison; to set a threshold value for the feature quantity; to further classify on the basis of the threshold value the pattern transfer information and the design pattern classified on the basis of the feature quantity; to verify whether the transfer pattern satisfies the threshold value; and to display the result of the verification.

According to a third aspect of the invention, there is provided a semiconductor device manufacturing method comprising: acquiring information on a transfer pattern created from a design pattern corresponding to a pattern to be formed on a substrate as pattern transfer information; comparing the design pattern with the transfer pattern; classifying the pattern transfer information and the design pattern on the basis of the feature quantity obtained from the comparison; setting a threshold value for the feature quantity; further classifying on the basis of the threshold value the pattern transfer information and the design pattern classified on the basis of the feature quantity; verifying whether the transfer pattern satisfies the threshold value; if the transfer pattern satisfies the threshold value, forming a mask according to a mask pattern based on the design pattern; and forming a pattern on the substrate using the mask.

### BRIEF DESCRIPTION OF THE SEVERAL VIEWS OF THE DRAWING

FIG. 1 is a flowchart for a pattern verification method according to a first embodiment of the invention;

FIGS. 2A and 2B are simplified diagrams to explain a gap between a design pattern and a transfer pattern;

FIG. 3 is a diagram showing the hotspots detected by the pattern verification method of FIG. 1 in such a manner that they are classified according to error level;

FIG. 4 is a diagram showing the hotspots detected by the pattern verification method of FIG. 1 in such a manner that they are classified into a plurality of groups according to error level;

FIGS. 5A to 5C are diagrams showing the results of pattern matching in the pattern verification method of FIG. 1 in such a manner that they are classified according to error level;

FIG. 6 shows the error spots included in a transfer pattern found out by pattern matching in the pattern verification method of FIG. 1 in such a manner that they are classified according to error level;

FIG. 7 shows the error spots included in a transfer pattern found out by pattern matching in the pattern verification method of FIG. 1 in such a manner that they are classified according to error level and error type;

FIG. 8 is a simplified block diagram of a pattern verification and modification system according to the first embodiment;

FIG. 9 is a simplified block diagram showing the relationship between a computer-readable recording medium in which a pattern verification program according to the first embodiment has been recorded and the pattern verification and modification system of FIG. 8;

FIGS. 10 to 14 are flowcharts to explain a pattern design method according to a second embodiment of the invention;

FIGS. 15A to 15E, FIGS. 16A to 16C, and FIGS. 17A and 17B are simplified diagrams to explain modification rules in the pattern design method of FIG. 10;

FIGS. 18 and 19 are simplified diagrams showing the results of the modification of the design pattern by the pattern design method of FIG. 10; and

FIG. 20 is a flowchart to explain a pattern design method according to a third embodiment of the invention.

### DETAILED DESCRIPTION OF THE INVENTION

Hereinafter, referring to the accompanying drawings, embodiments of the invention will be explained.

### First Embodiment

A first embodiment of the invention relates to a design pattern verification method, a design pattern verification system, and a design pattern verification program which are applied in creating a physical layout of a semiconductor integrated circuit pattern from design data on a semiconductor integrated circuit pattern. In the first embodiment, an explanation will be given as to a pattern verification method, a pattern verification system, and a pattern verification program which perform verification of the process margin of the pattern on a substrate concurrently with the creation of design data on a semiconductor integrated circuit pattern. In the first embodiment, the verification of the process margin of a pattern is virtual pattern matching. To perform verification concurrently during pattern design, it is necessary to process the spots to be verified at high speed with high accuracy. To do this, it is desirable to quickly extract data on a pattern to be verified from data on the entire design pattern through pattern matching and conduct a high-accuracy transfer simulation with the extracted pattern data.

(Pattern Verification Method)

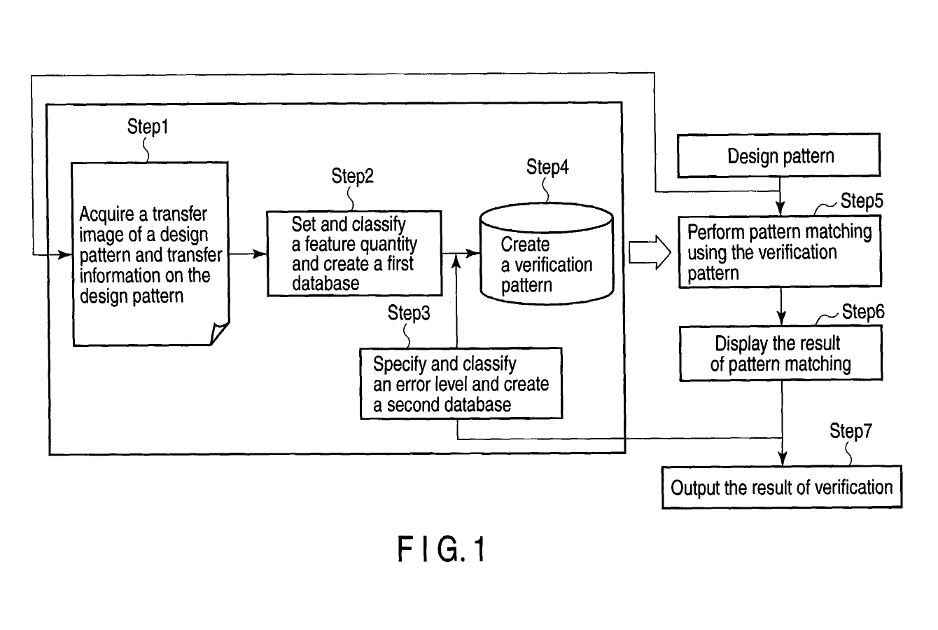

Hereinafter, a pattern verification method of the first embodiment will be explained in detail with reference to FIGS. 1 to 7.

As shown in a flowchart in FIG. 1, information on a transfer pattern created from a design pattern corresponding to a pattern to be formed on a substrate is acquired as pattern transfer information (Step 1).

Pattern transfer information in forming a design pattern on a semiconductor substrate under at least one specific process condition is acquired through, for example, simulation. At this time, pattern transfer information on the design patterns (data) of all patterns to be formed on the substrate is acquired. The pattern transfer information includes the shape of a pattern on the semiconductor substrate (silicon substrate), the image of a layout, and the transfer image of a design pattern corresponding to the pattern. The pattern transfer information includes not only just an image (transfer image) of the transfer pattern but also information on the shape and dimensions of the transfer pattern.

As described above, the transfer pattern used in the first embodiment is a pattern based on the data acquired through simulation, not a pattern actually transferred and formed on the semiconductor substrate. The transfer pattern of the first embodiment becomes a part of basic data in actually forming a pattern on a semiconductor substrate after the pattern verification method of the first embodiment is applied.

Accordingly, the transfer pattern of the first embodiment can be considered to be a part of the design pattern of a pattern to be formed on the semiconductor substrate. In this case, a design pattern serving as a basis for the transfer pattern of the first embodiment is referred to as a first semiconductor integrated circuit design pattern (a first design pattern) and a transfer pattern is referred to as a second semiconductor integrated circuit design pattern (a second design pattern), thereby distinguishing between the design pattern and the transfer pattern.

Next, the design pattern is compared with the transfer pattern and, on the basis of the feature quantity obtained from the comparison, pattern transfer information and design patterns are classified (Step 2).

Specifically, in Step 2, first, the design pattern is compared with the pattern transfer information acquired in Step 1 using predetermined means, thereby obtaining a feature quantity. The feature quantity represents, for example, the amount of difference in dimensions between the dimensions of the design pattern and dimensional information included in the pattern transfer information or the amount of difference in area between the shape of the design pattern and shape information included in the pattern transfer information. That is, the feature quantity obtained in Step 2 is the difference in dimensions or area between the design pattern and the transfer pattern corresponding to the design pattern. The predetermined means is means for measuring the difference in dimensions or area between the design pattern and the transfer pattern corresponding to the design pattern.

Information (data) on the image, shape, and dimensions of the transfer pattern included in the pattern transfer information acquired in Step 1 and information (data) on the design pattern corresponding to the transfer pattern are classified according to the feature quantity. With this classification, a first database is created which is composed of the design pattern and of the pattern transfer information built so as to have a data structure capable of being classified on the basis of the feature quantity. That is, data on the design patterns of all the patterns to be formed on the semiconductor substrate and data on a transfer image on the semiconductor substrate corresponding to the design pattern are prepared as the first database classified on the basis of the feature quantity. It is desirable for the data in the first database to be updated each time the design pattern is updated and its update history should be accumulated chronologically.

Next, a threshold value is set for the feature quantity obtained in Step 2 and the data on the pattern transfer information and the design pattern classified on the basis of the feature quantity are further classified on the basis of the threshold value (Step 3).

Specifically, in Step 3, a condition for performing verification of a process margin for a pattern formed on the semiconductor substrate is determined. The condition for performing verification is, for example, to detect and verify all detectable patterns whose lithographic margin on the semiconductor substrate has not reached an allowable error margin. Alternatively, the condition for performing verification is to detect and verify a so-called hotspot, a pattern whose lithographic margin is not completely zero “0” but significantly small. The criterion for determining how much each of the conditions has been satisfied is set as a threshold value for the feature quantity in a plurality of levels, depending on the degree to which each of the conditions has been fulfilled. At this time, a plurality of threshold values are classified according to the type of feature quantity, such as the difference in dimensions or the difference in area and then set separately. A plurality of threshold values may be classified according to not only the types of feature quantity but also the types of transfer patterns and then set separately. The type of transfer pattern means a pattern located in a specific part of the semiconductor substrate. Specifically, the type of transfer pattern means a line end part, a corner part, a T-junction part, or the like. Moreover, the threshold value for the feature quantity may be changed and set to a specific level according to the design method for a design pattern.

The pattern transfer information and design pattern data classified on the basis of the feature quantity and stored in the first database in Step 2 are further classified on the basis of the threshold value. With this classification, a second database is created which is composed of the design pattern and of data on the pattern transfer information built so as to have a data structure capable of being classified on the basis of the feature quantity and the threshold value.

Next, a pattern used for pattern verification is created from the design pattern data and pattern transfer information stored in the second database created in Step 3 (Step 4).

Specifically, for the design pattern data and pattern transfer information stored in the second database, a specific feature quantity and a threshold value are selected (specified) according to a desired verification condition. Accordingly, the design pattern data and pattern transfer information classified into a category satisfying the condition for performing pattern verification are selected from the second database. That is, a pattern (data) used for pattern verification is created suitably according to a condition for conducting pattern verification.

Next, a first pattern verification process of verifying whether the transfer pattern satisfies the threshold value is performed (Step 5).

Specifically, using the pattern selected in Step 4, the pattern matching of a design pattern to be verified and a transfer pattern corresponding to the design pattern is performed. More specifically, referring to data on each pattern stored in the second database, whether the transfer pattern (the second design pattern) coincides with the design pattern (the first design pattern) is verified on a threshold value basis. The design pattern used in Step 5 is supplied directly to Step 5 in parallel with Step 1 to Step 4, while Step 1 to Step 4 are in progress.

Here, “coincide” does not necessarily mean that the transfer pattern coincides with the design pattern 100 percent in form and dimensions. In the first embodiment, “coincide” means a process margin or lithographic margin for the transfer pattern has reached the allowable error margin. That is, pattern verification in the first embodiment is to determine whether a process margin or lithographic margin for the transfer pattern has reached the allowable error margin. Accordingly, a threshold value in the first embodiment is for setting an allowable error margin of the process margin or lithographic margin for the transfer pattern in a stepwise manner. As described above, it is desirable that the allowable error margin of a process margin or lithographic margin for the transfer pattern should be set to a suitable value as needed according to the shape, dimensions, configuration, layout, arrangement, and parts of the transfer pattern on the semiconductor substrate, and various elements, the types of interconnections, etc. based on the transfer pattern. Alternatively, it is desirable to set the allowable error margin of the process margin or lithographic margin for the transfer pattern to a suitable value as needed according to the design method for a design pattern.

The level of verification corresponds to determining what pattern is used as a matching pattern in verifying the design pattern. As described above, the first embodiment is characterized by holding verification patterns in such a manner that they are hierarchized on a threshold value basis. In the first embodiment, if a condition for verification is determined, a specific level of hierarchy (threshold value) is selected according to the condition and a pattern belonging to the selected hierarchy level among all the hierarchized verification patterns is used directly in pattern verification. This is a so-called default usage. The method of using a verification pattern in the first embodiment is not limited to the default usage. For example, first, a specific hierarchy level is selected from all the verification patterns existing in the second database. Then, use or nonuse of some of a plurality of verification patterns included in the selected hierarchy level may be selected. By doing this, a condition for verification may be selected flexibly. This is a so-called custom usage.

Next, the result of pattern verification (pattern matching) is displayed (Step 6).

Specifically, as a result of the pattern matching of the design pattern, where and how many transfer patterns whose process margin or lithographic margin has not reached the allowable error margin are included in the verified design pattern are displayed on a display or the like by the selected threshold value. At this time, if the verified transfer patterns include a transfer pattern that does not satisfy the threshold value related to the feature quantity, the transfer pattern should be set so as to be highlighted. Moreover, if the verified design patterns include a transfer pattern that does not satisfy the threshold value related to the feature quantity, the amount of the threshold value of the transfer pattern that does not satisfy the threshold value related to the feature quantity, a transfer image, a marker, and the like should be displayed so as to be superimposed on the transfer pattern. The pattern verification method of the first embodiment may be set so as to conduct pattern verification repeatedly a plurality of times, changing the threshold value each time one pattern verification is completed as shown by a loop composed of Step 3, Step 4, Step 5, and Step 6 in the flowchart of FIG. 1.

Finally, the result of the pattern verification (pattern matching) is output (Step 7).

This completes the pattern verification method of the first embodiment.

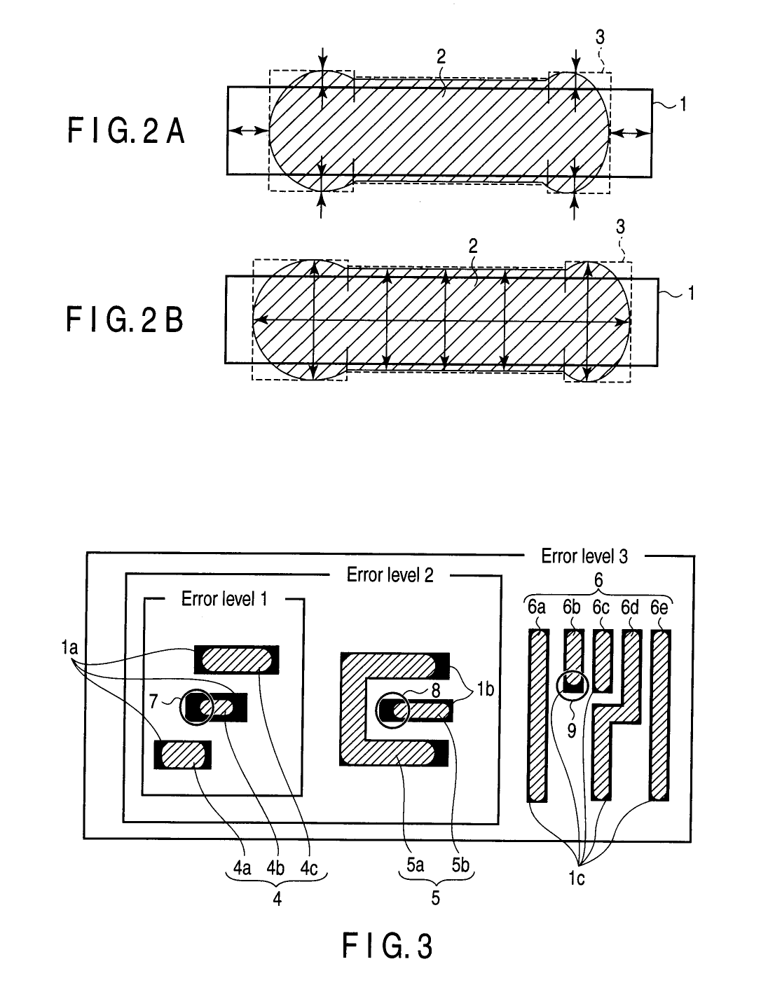

Next, referring to FIGS. 2A to 7, the pattern matching in Step 5 will be explained in detail.

FIGS. 2A and 2B schematically show the concept of a design pattern 1 and a transfer pattern 2 serving as a transfer image of the design pattern 1. In FIGS. 2A and 2B, a solid line represents the design pattern 1, a shaded area represents the transfer pattern 2, and a broken line represents a mask pattern 3. The arrows in FIG. 2A indicate a gap width between design pattern 1 and transfer pattern 2, that is, the amount of gap in position. The length of an arrow represents the amount of gap in position, that is, the degree of error. As the amount of gap in position between the design pattern 1 and the transfer pattern 2 becomes smaller, the length of the arrow becomes shorter. In other words, as the length of the arrow representing the degree of error to be verified in a pattern is made shorter, the allowable error margin for the amount of gap in position between the design pattern 1 and the transfer pattern 2 becomes narrower. That is, as the length of the arrow is made shorter, the accuracy of pattern verification becomes higher. The arrows in FIG. 2B represent the dimensions of transfer pattern 2. As in FIG. 2A, in FIG. 2B, to verify even an error shown by a short arrow means to verify even a microscopic transfer pattern 2, meaning that the accuracy of verification is high.

FIG. 3 shows a plurality of hotspots 7, 8, 9 and their error levels used in the first embodiment. Specifically, in FIG. 3, a plurality of transfer patterns 4, 5, 6 extracted from a plurality of design patterns 1a, 1b, 1c, three hotspots 7, 8, 9 included in the transfer patterns 4, 5, 6, and an area about 3 μm around each of the transfer patterns 4, 5, 6 are classified according to error level. The shaded parts in the design patterns 1a, 1b, 1c are transfer images of the design patterns 1a, 1b, 1c. That is, the shaded parts in FIG. 3 are transfer patterns 4, 5, 6. The black parts in FIG. 3 are the areas about 3 μm around the transfer patterns 4, 5, 6. In FIG. 3, the parts enclosed with a circle are hotspots 7, 8, 9. When a threshold value has been determined (selected) in Step 4, a hotspot at the error level corresponding to the specified threshold value is selected from a plurality of hotspots 7, 8, 9 included in the design patterns 1a, 1b, 1c.

Of the transfer patterns 4, 5, 6, the transfer pattern 4 at the left of FIG. 3 is composed of three straight line patterns 4a, 4b, 4c laid out so as to be in parallel with one another in the longitudinal direction. Of the line patterns 4a, 4b, 4c, the difference between both ends of the central line pattern 4b and those of the design pattern 1a is larger than the difference between both ends of each of the upper and lower line patterns 4a, 4c and those of the design pattern 1a. Accordingly, the hotspot 7 included in the central line pattern 4b is a high error level of hotspot. If the line pattern 4b including such a hotspot 7 is transferred directly onto a wafer according to the transfer image, the tip parts will be rounded. Consequently, the finished line pattern 4b will be shorter than the design pattern 1a. Here, the hotspot 7, the transfer pattern 4 including the hotspot 7, and the design pattern 1a corresponding to the transfer pattern 4 are classified into error level 1.

The transfer pattern 5 in the central part of FIG. 3 is laid out so that one straight line pattern 5b may be inserted into a box-shaped pattern 5a. As in the line pattern 4b, in the transfer pattern 5, one end of the line pattern 5b is a hotspot 8. The difference between the line pattern 5b and the design pattern 1b is smaller than the difference between the line pattern 4b and the design pattern 1a. Accordingly, the error level of the hotspot 8 is lower than that of the hotspot 7. Here, the hotspot 8, the transfer pattern 5 including the hotspot 8, and the design pattern 1b corresponding to the transfer pattern 5 are classified into error level 2 whose error (risk) is smaller than that of error level 1.

The transfer pattern 6 at the right in FIG. 3 is laid out so that two short straight line patterns 6b, 6c and a bent pattern 6d cranked in the middle may be laid side by side between two long straight line patterns 6a, 6e. As in the line patterns 4b, 5b, in the transfer pattern 6, one end of the second line pattern 6b from the left is a hotspot 9. The difference between the line pattern 6b and the design pattern 1c is smaller than the difference between the line pattern 5b and the design pattern 1b. Accordingly, the error level of the hotspot 9 is lower than that of the hotspot 8. Here, the hotspot 9, the transfer pattern 6 including the hotspot 9, and the design pattern 1c corresponding to the transfer pattern 6 are classified into error level 3 whose error (degree of risk) is smaller than that of error level 2.

As described above, when the error level (threshold value) is high, this means that an error, such as a gap in position or a gap in dimensions, is large and there is a high possibility that the allowable error margin will be exceeded. Conversely, when the error level is low, this means that an error, such as a gap in position or a gap in dimensions, is small and it is less likely that the allowable error margin will be exceeded. Accordingly, as the error level of a hotspot to be detected is made lower, the accuracy of pattern verification becomes higher. When a specific error level is selected, the hotspots belonging to the error level and the hotspots belonging to the error levels higher than the selected error level are all detected.

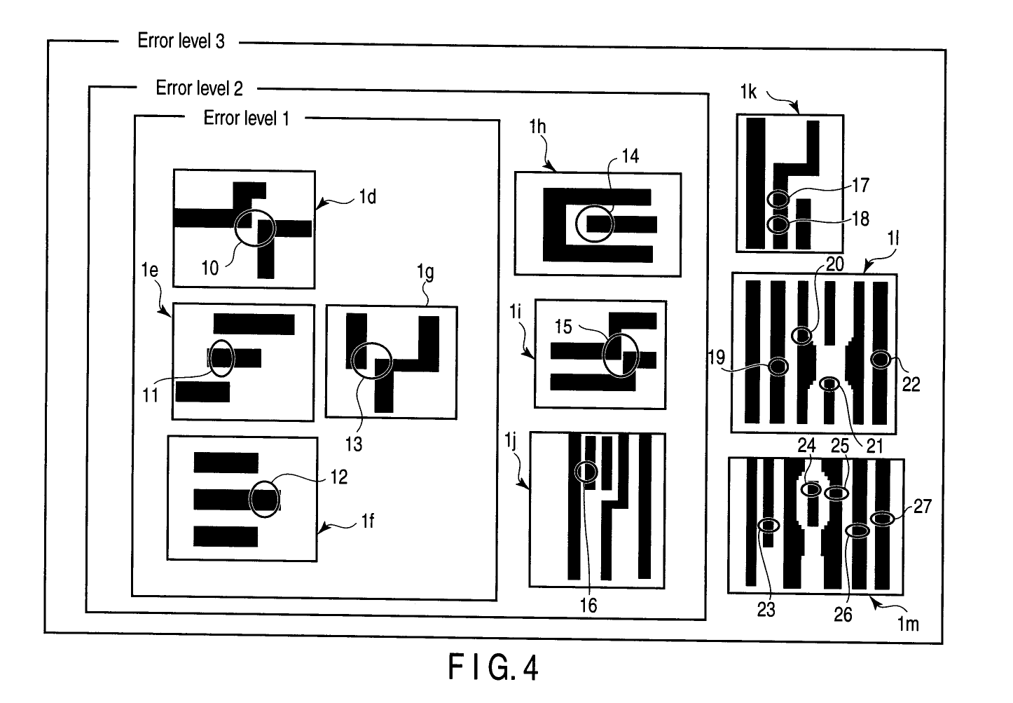

As in FIG. 3, in FIG. 4, a plurality of design patterns 1d, 1e, 1f, 1g, 1h, 1i, 1j, 1k, 1l, 1m and a plurality of hotspots 10, 11, 12, 13, 14, 15, 16, 17, 18, 19, 20, 21, 22, 23, 24, 25, 26, 27 included in the transfer patterns extracted from the design patterns 1d to 1m are classified according to error level. In FIG. 4, a graphic representation of the transfer patterns serving as the transfer images of the design patterns 1d to 1m is not given. FIG. 4 differs from FIG. 3 in that a plurality of design patterns 1d to 1m and hotspots 10 to 27 are classified into error levels 1 to 3.

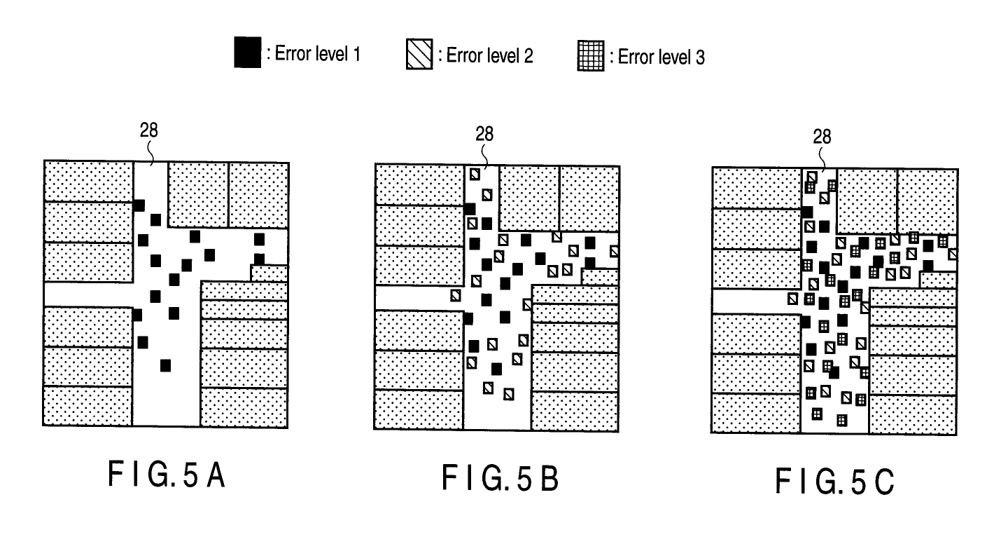

Next, FIGS. 5A to 5C each show, on an error level basis, a state where invalid patterns detected through pattern matching and not satisfying a verification condition, such as the feature quantity, threshold value, or allowable error, were distributed on a semiconductor substrate.

FIG. 5A shows the result of pattern matching of the design patterns 1d to 1g classified into error level 1 of FIG. 4 when the verification condition was set to error level 1. Error level 1 of FIG. 4 is the same as error level 1 of FIG. 3. Accordingly, each of the design patterns 1d to 1g is a pattern which creates a transfer image that causes the same amount of gap in position as the design pattern 1a classified into error level 1 of FIG. 3 or a pattern that creates a transfer image including a spot where the same gap in dimensions occurs. In FIG. 5A, a plurality of black boxes represent parts cut out from the design patterns 1d to 1g belonging to error level 1 and the semiconductor substrate (semiconductor chip) 28 in their surrounding areas. Accordingly, the result of pattern matching shown in FIG. 5A has shown that there are as many design patterns 1d to 1g belonging to error level 1 in the semiconductor chip 28 as there are black boxes in FIG. 5A. That is, it is seen that there are invalid patterns (critical patterns) 1d to 1g conflicting with error level 1 and hotspots 10 to 13 in the areas shown by the black boxes in FIG. 5A.

Next, FIG. 5B shows the result of pattern matching of the design patterns 1d to 1g classified into error level 1 and the design patterns 1h to 1j classified into error level 2 in FIG. 4 when the verification condition was set to error level 2. Error level 2 of FIG. 4 is the same as error level 2 of FIG. 3. Accordingly, each of the design patterns 1h to 1i belonging only to error level 2 of FIG. 4 is a pattern which creates a transfer image that causes the same amount of gap in position as the design pattern 1b classified only into error level 2 of FIG. 3 or a pattern that creates a transfer image including a spot where the same gap in dimensions occurs. In FIG. 5B, a plurality of hatched boxes represent parts cut out from the design patterns 1h to 1j belonging only to error level 2 and the semiconductor chip 28 in their surrounding areas. The result of pattern matching shown in FIG. 5B has shown that there are as many design patterns 1d to 1g, 1h to 1j belonging to error level 1 and error level 2 in the semiconductor chip 28 as there are black boxes and hatched boxes in FIG. 5B. Moreover, the result of pattern matching in FIG. 5B has shown that, since the verification condition is lowered from error level 1 to error level 2, more invalid patterns (critical patterns) 1h to 1j and hotspots 14 to 16 have been detected than in the result of pattern matching of FIG. 5A with the verification condition set to error level 1.

Next, FIG. 5C shows the result of pattern matching of the design patterns 1d to 1g classified into error level 1, the design patterns 1h to 1j classified into error level 2, and the design patterns 1k to 1m classified into error level 3 in FIG. 4 when the verification condition was set to error level 3. Error level 3 of FIG. 4 is the same as error level 3 of FIG. 3. Accordingly, each of the design patterns 1k to 1m belonging only to error level 3 of FIG. 4 is a pattern which creates a transfer image that causes the same amount of gap in position as the design pattern 1c classified only into error level 3 of FIG. 3 or a pattern that creates a transfer image including a spot where the same gap in dimensions occurs. In FIG. 5C, a plurality of mesh boxes represent parts cut out from the design patterns 1k to 1m belonging only to error level 3 and the semiconductor chip 28 in their surrounding areas. The result of pattern matching shown in FIG. 5C has shown that there are as many design patterns 1d to 1g, 1h to 1j, 1k to 1m belonging to error level 1 to error level 3 in the semiconductor chip 28 as there are black boxes, hatched boxes, and mesh boxes in FIG. 5C. Moreover, the result of pattern matching in FIG. 5C has shown that, since the verification condition is lowered from error level 2 to error level 3, more invalid patterns (critical patterns) 1k to 1m and hotspots 17 to 27 have been detected than in the result of pattern matching of FIG. 5A with the verification condition set to error level 1 and the result of pattern matching of FIG. 5B with the verification condition set to error level 2.

Accordingly, of the verification results shown in FIGS. 5A to 5C, the result of pattern matching with the verification condition set to the lowest error level 3 has shown the highest pattern verification accuracy, as shown in FIG. 5C. When pattern matching is performed a plurality of times, it is desirable to detect hotspots 10 to 27 at all error levels in the first evaluation and grasp the distribution state of the entire chip 28. Therefore, in the first pattern matching, the verification condition is set to the lowest error level 3 and evaluations are made. Then, using the result of the evaluation, the policy of modifying a target design pattern is determined.

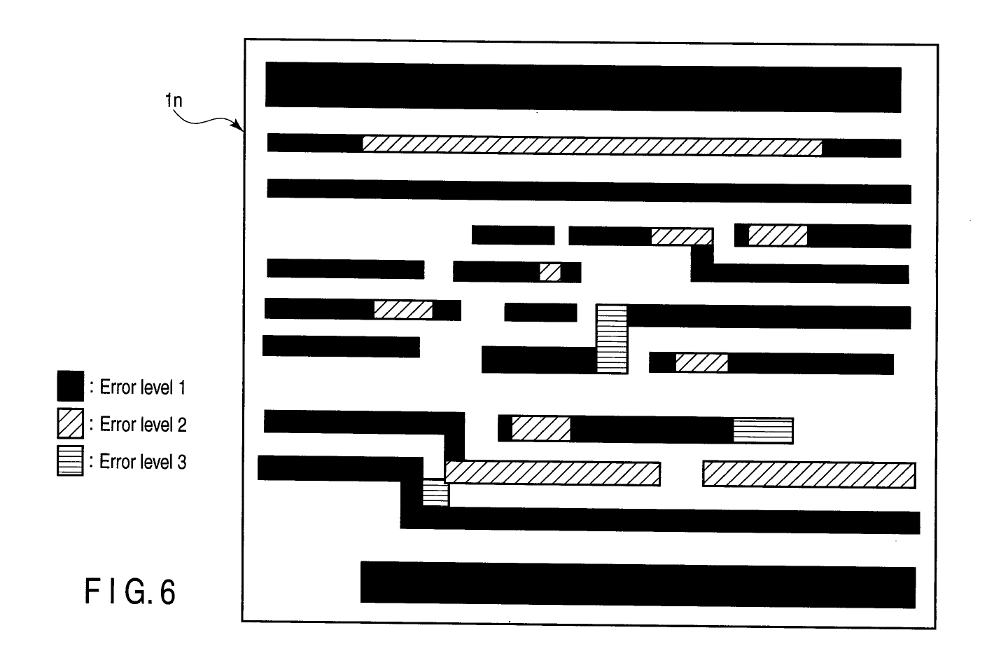

Next, in FIG. 6, error spots included in a design pattern in detected through pattern matching in the pattern verification method of the first embodiment are classified according to error level. In FIG. 6, a plurality of black parts represent errors belonging only to error level 1. A plurality of hatched parts in FIG. 6 represent errors belonging only to error level 2. A plurality of crossed parts in FIG. 6 represent errors belonging only to error level 3.

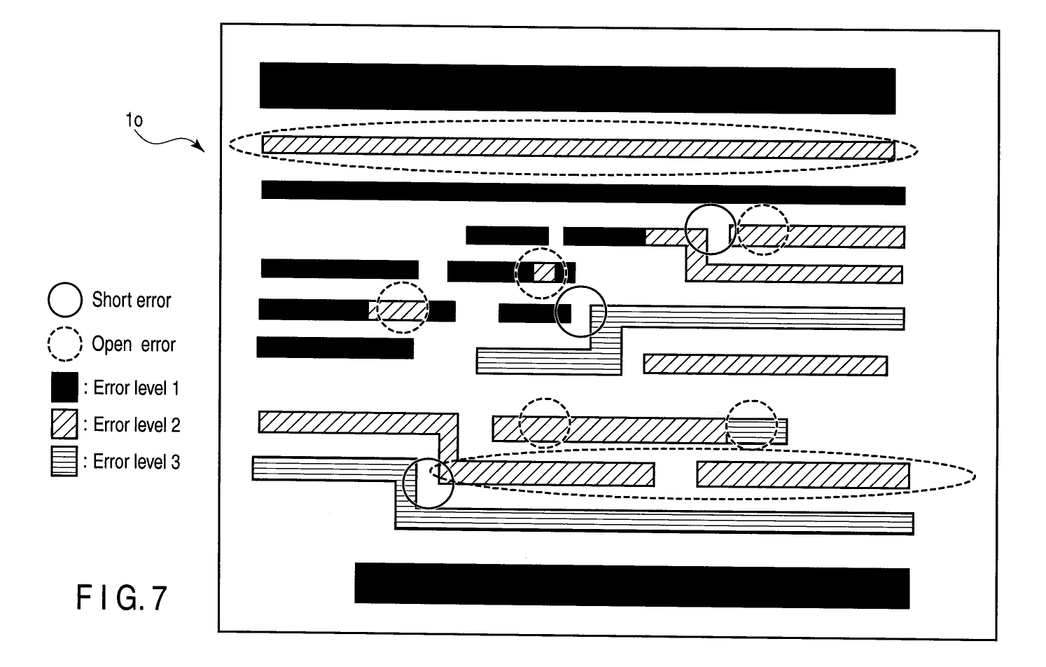

Next, in FIG. 7, error spots included in the design pattern 1o detected through pattern matching in the pattern verification method of the first embodiment are classified according to error level and error type. As in FIG. 6, in FIG. 7, a plurality of black parts represent errors belonging only to error level 1. A plurality of hatched parts in FIG. 7 represent errors belonging only to error level 2. A plurality of crossed parts in FIG. 7 represent errors belonging only to error level 3. In FIG. 7, areas enclosed with solid-line circles represent open-error spots. Areas enclosed with broken-line circles represent short-error spots.

As shown in FIGS. 3, 4, 6, and 7, an invalid pattern which does not satisfy the threshold value related to the feature quantity is composed of a single figure or a plurality of figures.

(Pattern Verification System)

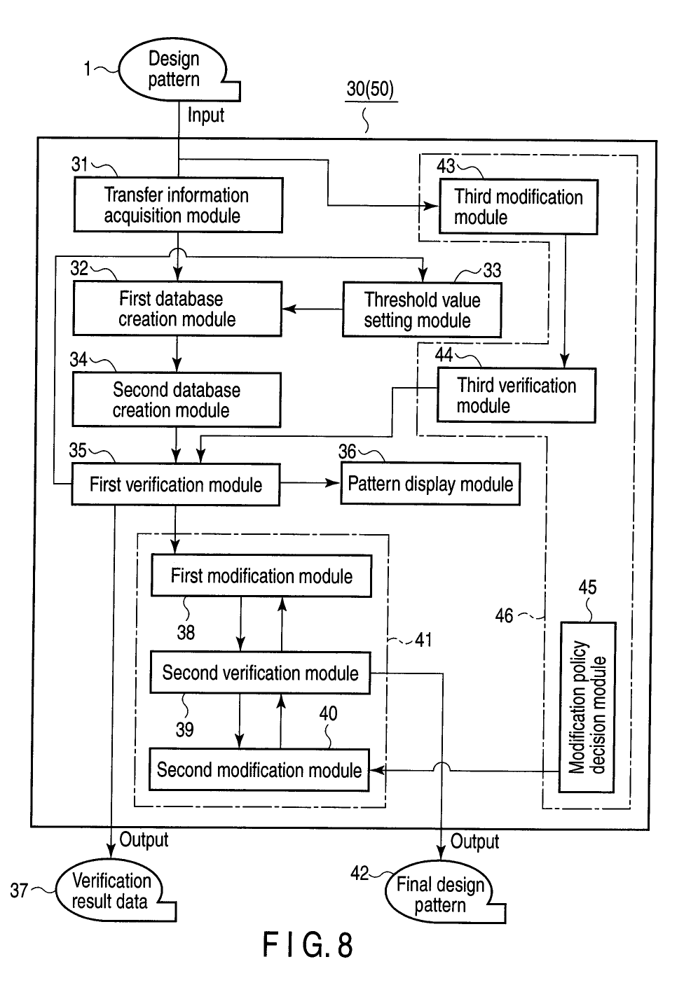

Next, a pattern verification system according to the first embodiment will be explained with reference to FIG. 8. FIG. 8 is a block diagram schematically showing a configuration of the pattern verification system of the first embodiment. As shown in FIG. 8, the pattern verification system 30 comprises a transfer information acquisition module 31, a first database creation module 32, a threshold value setting module 33, a second database creation module 34, a first verification module 35, and a pattern display module 36. The pattern verification system 30 further comprises a first pattern modification unit 41 composed of a first modification module 38, a second verification module 39, and a second modification module 40 as shown by a dashed-dotted line in FIG. 8. The pattern verification system 30 still further comprises a second pattern modification unit 46 composed of a third modification module 43, a third verification module 44, and a modification policy decision module 45 as shown by a double-dot dashedline in FIG. 8. Having the first and second pattern modification units 41, 46, the pattern verification system 30 not only implements the pattern verification method of the first embodiment but also functions as a pattern design system which implements a pattern design method according to a second and a third embodiment of the invention described later. Accordingly, the pattern verification system 30 should be referred to as a pattern verification and design system.

In the first embodiment, of the components included in the pattern verification and design system 30, only the functions of the components excluding the first and second pattern modification units 41, 46 will be explained. Specifically, the pattern verification and design system 30 will be explained as a pattern verification system which implements a pattern verification method described in the flowchart of FIG. 1. The functions of the first and second pattern modification units 41, 46 included in the pattern verification and design system 30 and a pattern design method using the units 41, 46 will be explained in the second and third embodiment later.

First, as shown in FIG. 8, design data for design pattern 1 is input to the transfer information acquisition module 31. Then, the transfer information acquisition module 31 applies transfer simulation on the semiconductor substrate 28 on the basis of the input design data for design pattern 1, acquiring information on the transfer patterns 2, 4, 5, 6 as pattern transfer information. That is, the transfer information acquisition module 31 executes Step 1 in the flowchart of FIG. 1. After executing Step 1, the transfer information acquisition module 31 sends the design data for design pattern 1 and the acquired pattern transfer information to the first database creation module 32.

The first database creation module 32 compares the design pattern 1 with the transfer patterns 2, 4, 5, 6 on the basis of the design data for design pattern 1 and the acquired pattern transfer information received from the transfer information acquisition module 31. Then, on the basis of the feature quantity obtained from the comparison, the first database creation module 32 classifies the pattern transfer information and the design data for design pattern 1, thereby creating a first database. That is, the first database creation module 32 executes Step 2 in the flowchart of FIG. 1. After executing Step 2, the first database creation module 32 sends to the second database creation module 34 the pattern transfer information and the design data for design pattern 1 classified on the basis of the feature quantity stored in the first database.

The threshold value setting module 33 sets a threshold value for the feature quantity obtained by the first database creation module 32. That is, the threshold value setting module 33 executes a pre-process of Step 3 in the flowchart of FIG. 1.

The first database creation module 32 sends the data stored in the first database created by the first database creation module 32 to the second database creation module 34 without changing the data structure. That is, the first database creation module 32 sends to the second database creation module 34 the pattern transfer information and the design data for design pattern 1 classified on the basis of the feature quantity. At the same time, the threshold value setting module 33 sends data on the threshold value for the feature quantity set by the threshold value setting module 33 to the second database creation module 34 via the first database creation module 32. Receiving these pieces of information (data), the second database creation module 34 further classifies, on the basis of the threshold value, the pattern transfer information and the design data for design pattern 1 classified on the basis of the feature quantity by the first database creation module 32, thereby creating a second database. That is, the second database creation module 34 executes a post-process of Step 3 in the flowchart of FIG. 1. After executing the post-process in Step 3, the second database creation module 34 sends to the first verification module 35 the pattern transfer information and the design data for design pattern 1 classified on the basis of the feature quantity and threshold value stored in the second database.

After receiving the pattern transfer information and the design data for design pattern 1 classified on the basis of the feature quantity and threshold value from the second database creation module 34, the first verification module 35 creates a pattern used for pattern verification, using those items of data. Then, using the created verification pattern, the first verification module 35 conducts pattern verification whereby whether the transfer pattern satisfies the threshold value is verified. Finally, the first verification module 35 outputs the result 37 of the pattern verification (pattern matching) as data outside the pattern verification system 30. That is, the first verification module 35 executes Step 4, Step 5, and Step 7 in the flowchart of FIG. 1.

The pattern display module 36 displays the result of the pattern verification conducted by the first verification module 35. That is, the pattern display module 36 executes Step 6 in the flowchart of FIG. 1.

(Pattern Verification Program)

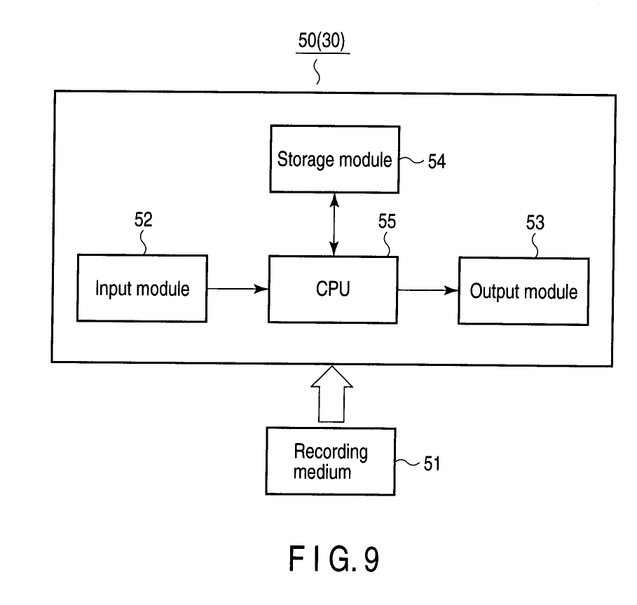

Next, a pattern verification program according to the first embodiment and a computer-readable recording medium in which the pattern verification program has been recorded will be explained with reference to FIG. 9. FIG. 9 is a block diagram schematically showing the relationship between a recording medium 51 in which a pattern verification program according to the first embodiment has been recorded and the pattern verification and design system 30 of FIG. 8. The program can be read by a computer 50. The pattern verification program and recording medium 51 according to the first embodiment not only operates the pattern verification and design system 30 of FIG. 8 but also controls its operation, thereby implementing the pattern verification method shown in the flowchart of FIG. 1.

The pattern verification method composed of Step 1 to Step 7 in the flowchart of FIG. 1 is virtually made up of data processing steps that can be processed by the computer 50 of FIG. 9. Such a pattern verification method is realized by the computer 50 whose operation is controlled by reading the pattern verification program of the first embodiment recorded in the recording medium 51, such as a magnetic disk, an optical disk, or a semiconductor memory. At the same time, the pattern verification system 30 of FIG. 8 is realized by the computer 50 whose operation is controlled by reading the pattern verification program of the first embodiment recorded in the recording medium 51. That is, the pattern verification method shown in the flowchart of FIG. 1 can be implemented by the pattern verification system 30 realized by the computer 50 whose operation is controlled by reading the pattern verification program of the first embodiment recorded in the recording medium 51. Hereinafter, an explanation will be given regarding the pattern verification system 30 of FIG. 8 as the computer 50 of FIG. 9.

In FIG. 9, the input sections of the transfer information acquisition module 31, first database creation module 32, threshold value setting module 33, second database creation module 34, first verification module 35, and pattern display module 36 are treated collectively as an input module 52 of the computer 50. Moreover, in FIG. 9, the output sections of the transfer information acquisition module 31, first database creation module 32, threshold value setting module 33, second database creation module 34, first verification module 35, and pattern display module 36 are treated collectively as an output module 53 of the computer 50. In addition, in FIG. 9, the storage sections of the transfer information acquisition module 31, first database creation module 32, threshold value setting module 33, second database creation module 34, first verification module 35, and pattern display module 36 are treated collectively as a storage module 54 of the computer 50. Furthermore, in FIG. 9, the computing sections of the transfer information acquisition module 31, first database creation module 32, threshold value setting module 33, second database creation module 34, first verification module 35, and pattern display module 36 are treated collectively as a CPU (arithmetic processing module) 55 of the computer 50. The CPU 55 acting as an arithmetic processing module is also referred to as a data processing module or a program executing module.

First, as shown in FIG. 9, the pattern verification program recorded in the recording medium 51 is read into the computer 50. Specifically, the CPU 55 is caused to read the pattern verification program recorded in the recording medium 51 via the input module 52 of the computer 50. The pattern verification program read by the CPU 55 is sent to the storage module 54 of the computer 50, which stores the program. Thereafter, the CPU 55 operates the computer 50 suitably on the basis of the pattern verification program stored in the storage module 54 so that the pattern verification system 30 may implement the pattern verification method properly. That is, the pattern verification program causes the transfer information acquisition module 31, first database creation module 32, threshold value setting module 33, second database creation module 34, first verification module 35, and pattern display module 36 in the pattern verification system 30 to operate suitably so that the pattern verification system 30 may implement the pattern verification method properly as explained with reference to FIGS. 1 to 8.

After a series of pattern verification processes has been completed, the result of the processes are output as data 37 on the verification result via the output module 53 of the computer 50 (pattern verification system 30) outside the computer 50 as shown in FIG. 8. At this time, the result of the pattern verification process performed by the computer 50 may be stored in the storage module 54. As described above, the pattern verification system 30 of the first embodiment is realized properly by not only reading the pattern verification program into the computer 50 but also causing the read-in pattern verification program to control the operation of the computer 50. The pattern verification method of the first embodiment is implemented properly by the pattern verification system 30 acting as the computer 50 which has read in the pattern verification program recorded in the recording medium 51.

The data for design pattern 1 as input data and the pattern verification program have not necessarily been written in the input recording medium 51. The data for design pattern 1 and the pattern verification program may be transferred to the computer 50 via a specific communication medium when pattern verification is conducted. Although not shown, the data for design pattern 1 and the pattern verification program may be configured to be downloaded into the storage module 54 of the computer 50 via various telecommunication lines, such as the Internet or a LAN, or a communication medium (input device), such as a network interface. In this case, the data for design pattern 1 and the pattern verification program have only to be stored in various external computers or storage devices connected to the pattern verification system 30 acting as the computer 50.

Moreover, as long as the data for design pattern 1 and the pattern verification program have been recorded in the pattern verification system 30 acting as the computer 50 in a readable or executable manner, they may be recorded in any state or in any form. For example, as the input recording medium 51 in which the data for design pattern 1 and the pattern verification program are recorded, a magnetic disk, such as a flexible disk or a hard disk, an optical disk, such as a CD, a DVD, or an MO, or a semiconductor memory may be used. This holds true for the verification result as output data and an output recording medium (not shown) in which the verification result is recorded. Moreover, as the storage module 54 of the computer 50, a recording medium or a storage unit which enables its recorded data or program to be rewritten or updated as needed may be used. Such a recording medium or a storage unit includes a magnetic disk, such as a flexible disk or a hard disk, an optical disk, such as a CD, a DVD, or an MO, and a semiconductor memory. In addition, the telecommunication line connected to the computer 50 may be either wired or wireless.

As described above, with the first embodiment, it is possible to provide a pattern verification method, pattern verification system, and pattern verification program which are capable of forming microscopic patterns efficiently with high accuracy. Specifically, with the first embodiment, when patterns are designed, not only is a threshold value for a process margin selected, but also a library of patterns whose process margin has not reached the allowable error margin is created. Taking in the information in the library, pattern design and process verification are conducted concurrently. More specifically, when patterns, including interconnections, are designed, the result of the process verification is fed back to the pattern design process, thereby making a pattern design in parallel with a local modification to the design pattern, while timing closure on the design side and the detection of defects are being taking into account.

By doing this, a reduction in the total cost required for the pattern design and a decrease in the design time can be realized. Furthermore, the load on the post-pattern design process can be reduced remarkably. As a result, the load on the design of the entire semiconductor device can be reduced remarkably. Accordingly, owing to the reduction in production cost, it is possible to reduce the load on the OPC verification, process verification, and the like on the manufacture side and realize better efficiency in semiconductor device design.

### Second Embodiment

Next, a second embodiment of the invention will be explained. In the second embodiment, the same parts as those of the first embodiment are indicated by the same reference numeral and a detailed explanation of them will be omitted.

The second embodiment relates to a pattern design method, a pattern design system, and a pattern design program which make use of the pattern verification method, pattern verification system, and pattern verification program of the first embodiment, respectively. Specifically, in the second embodiment, a pattern design method, a pattern design system, and a pattern design program will be explained which, when design data on a semiconductor integrated circuit pattern is created, verify a process margin concurrently with pattern design and modify a design pattern whose process margin has not reached an allowable error margin by the time the chip design has been completed. In the second embodiment, the layout of the individual functional blocks of a semiconductor integrated circuit and the interconnections between the individual functional blocks are assumed in the pattern design process of the semiconductor integrated circuit.

(Pattern Design Method)

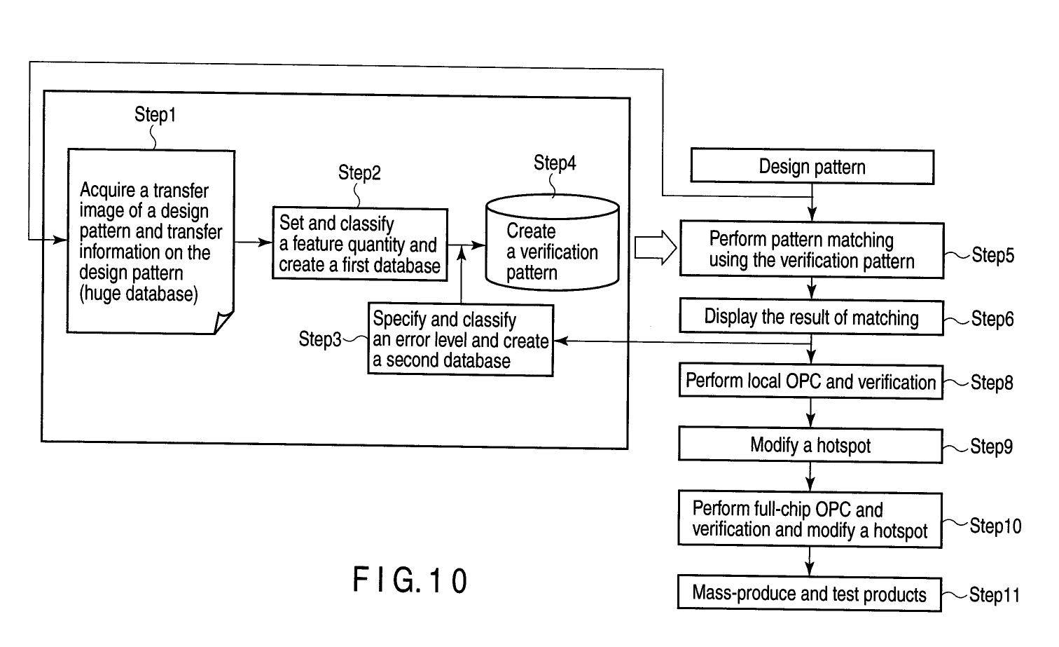

Hereinafter, a pattern design method according to the second embodiment will be explained in detail with reference to FIG. 10.

As shown in a flowchart in FIG. 10, first, Step 1 to Step 6 are carried out as in the pattern verification method of the first embodiment of FIG. 1. In the second embodiment, however, pattern transfer information acquired in Step 1 is stored in a huge database. Pattern matching in Step 5 is performed using a verification pattern created with the error level set to “1” in FIGS. 3 and 4.

Next, in pattern matching in Step 5, if an invalid pattern which does not satisfy the threshold value for the feature quantity has been detected in the design pattern 1, a transfer image of a surrounding area including the invalid pattern is acquired. At the same time, the invalid pattern is modified on the basis of the result of verifying the acquired transfer image so that the invalid pattern may satisfy the threshold value for the feature quantity. Then, it is verified whether the modified invalid pattern satisfies the threshold value for the feature quantity (Step 8).

Specifically, in Step 8, not only are the invalid pattern and a transfer pattern included in its surrounding area extracted, but also the invalid pattern is subjected to proximity correction (PC) so that the lithographic margin of the invalid pattern may reach the allowable error margin. The proximity correction (PC) includes, for example, optical proximity correction (OPC) or process proximity correction (PPC). In the second embodiment, however, the invalid pattern and its surrounding area are subjected to optical proximity correction (OPC). In this case, the degree of the OPC is adjusted suitably on an invalid pattern basis according to the degree of invalidity of the invalid pattern so that the lithographic margin of the invalid pattern may reach at least the allowable error margin. The transfer image of the area (invalid pattern) subjected to the OPC process is acquired again and then the transfer image is subjected to lithographic verification.

Next, if the result of lithographic verification in Step 8 has shown that a hotspot not satisfying the threshold value for the feature quantity has been detected in the area subjected to the OPC process, a transfer image of the surrounding area including the hotspot is acquired. At the same time, the hotspot is modified on the basis of the result of verifying the acquired transfer image so that the hotspot may satisfy the threshold value for the feature quantity (step 9).

Specifically, in Step 9, the hotspot and a transfer pattern included in its surrounding area are extracted and the hotspot is further modified so that the lithographic margin of the hotspot may reach the allowable error margin. For example, a pattern corresponding to the hotspot and its surrounding patterns included in the design pattern 1 subjected to the OPC process in Step 8 or a space pattern between those patterns are subjected to the process of adding, deleting, or moving a pattern. At this time, various pieces of information on the shape and dimensions of the modified hotspot (invalid pattern) and on the area including the invalid pattern subjected to a modification process according to the degree of invalidity (error) are caused to correspond to the description of the modification to which the invalid pattern has been subjected. It is desirable that the information and the description of the modification should be classified and stored (recorded) according to the shape, dimensions, and degree of error of the invalid pattern. The information recorded in Step 9 also includes the coordinates and layer number of the modified invalid pattern.

Accordingly, in a case where pattern verification is conducted a plurality of times, when a pattern similar to a once-recorded invalid pattern is modified, the modifying process can be carried out quickly and efficiently by making the labor and time required to consider a method for and the degree of modification from the beginning again unnecessary. For example, in Step 10 described below, when the entire surface of the semiconductor substrate 28 for the design pattern 1 is subjected to the final proximity correction and verification, the process can be performed smoothly, while the processing condition is being changed suitably, properly, and quickly.

Thereafter, the processes in Step 8 and Step 9 are carried out repeatedly a plurality of times until the entire surface of the semiconductor substrate 28 has been subjected to the processes. That is, all of the design patterns 1 formed on the semiconductor substrate 28 are subjected to a full-chip OPC process, lithographic verification, and hotspot modification (Step 10).

After it has been determined in Step 10 that there are no hotspots in any of the design patterns 1, a semiconductor chip 28 provided with the layout of the individual functional blocks of the semiconductor integrated circuit and the interconnections between the individual functional blocks on the basis of the design pattern 1 is produced in large quantities. These semiconductor chips 28 are tested (step 11).

This completes the pattern design method of the second embodiment. As described above, the pattern design method of the second embodiment is virtually a combination of the pattern verification method explained in the first embodiment and the pattern modification method composed of Step 8 to Step 11 in the flowchart of FIG. 10. With those processes, after the layout of the individual functional blocks of the semiconductor integrated circuit and the interconnections between the individual functional blocks have been completed in the pattern design stage, lithographic margin deficiency errors in the critical spots (hotspots) detected through pattern matching have already been corrected. This reduces the load on the artwork in Step 10. Taking the purpose of pattern design into account, the pattern design method of the second embodiment may be configured to end in Step 10.

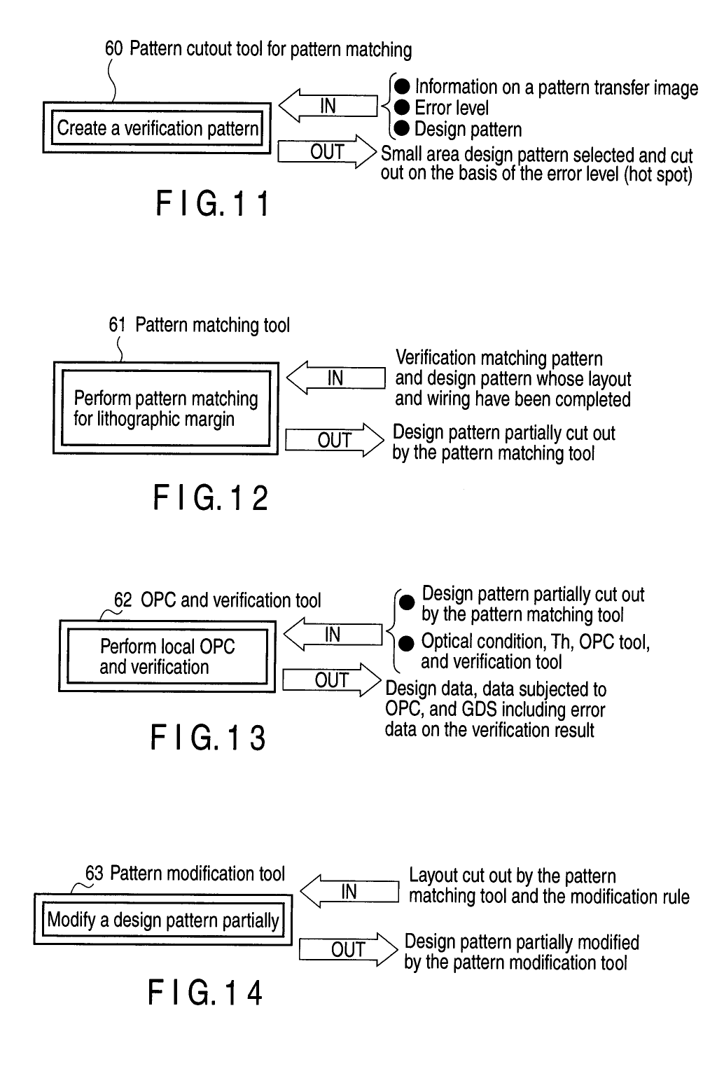

Next, characteristic parts of the pattern design method of the second embodiment will be explained in detail with reference to FIGS. 11 to 14. FIGS. 11 to 14 schematically show tools and their functions used in the pattern design method of the second embodiment.

First, using a pattern cutout tool 60 for pattern matching shown in FIG. 11, a matching pattern is created. That is, a verification pattern used in Step 4 of FIG. 10 is created using the matching pattern cutout tool 60. Specifically, first, the matching pattern cutout tool 60 is installed in the first verification module 35 included in the pattern verification and design system 30 shown in the block diagram of FIG. 8 in the first embodiment. Then, the second database creation module 34 of FIG. 8 inputs the data for the design pattern 1, information on the transfer image of the design pattern 1 (pattern transfer information), and a previously registered error level (threshold value) to the matching pattern cutout tool 60 installed in the first verification module 35. Then, the matching pattern cutout tool 60 outputs a small hotspot area selected and locally cut out from the design pattern 1 on the basis of the input error level. The hotspot is the same as, for example, the hotspot of FIG. 3 referred to in the first embodiment.

The design pattern 1 input to the matching pattern cutout tool 60 may be a design pattern or another generation design pattern to be subjected to a verification and modification process in a process after the pattern matching process in Step 5. A design pattern to be input differs according to the generation and the design pattern used for verification.

Next, using a pattern matching tool 61 shown in FIG. 12, pattern verification of the design pattern 1 is performed. That is, using the pattern matching tool 61, the pattern matching of the lithographic margin in Step 5 of FIG. 10 is performed. Specifically, first, the pattern matching tool 61 is installed in the first verification module 35 of the pattern verification and design system 30 in the block diagram of FIG. 8. Then, data on the verification matching pattern (hotspot) created by the matching pattern cutout tool 60 and data on the design pattern 1 provided with the layout of the individual functional blocks of the semiconductor integrated circuit and the interconnections between the individual functional blocks are input to the pattern matching tool 61. If the design pattern 1 includes a hotspot, a design pattern in an area with a radius of about 3 μm centering on the hotspot (critical spot) is partially cut out and output from the entire design pattern 1 by the pattern matching tool 61. Information on the cut-out area is sent to an OPC and verification tool 62 and is used for a final pattern verification using transfer simulation.

Next, using the OPC and verification tool 62 of FIG. 13, local OPC and verification in Step 8 of FIG. 10 are performed. Specifically, the OPC and verification tool 62 is installed in a first modification module 38 and a second verification module 39 (which will be explained later) included in the pattern verification and design system 30 shown in the block diagram of FIG. 8. Then, data on the area surrounding the hotspot cut out from the design pattern 1 by the pattern matching tool 61, the optical condition for pattern transfer, the threshold value of exposure amount (Th) of the pattern transfer device, the OPC rules, the verification rules, and other conditions are input to the OPC and verification tool 62 installed in the first modification module 38. Then, the OPC and verification tool 62 subjects each layer on which the design pattern 1 provided with the layout of the individual functional blocks of the semiconductor integrated circuit and the interconnections between the individual functional blocks to an OPC process under the optimized condition for products.

After the OPC process carried out by the OPC and verification tool 62 installed in the first modification module 38, the result of the OPC process is sent to the OPC and verification tool 62 installed in the second verification module 39. Then, the OPC and verification tool 62 installed in the second verification module 39 calculates the amount of gap in position between the pattern formed on the wafer 28 and the design pattern 1 on the basis of the result of the OPC process received from the OPC and verification tool 62 installed in the first modification module 38, the product optimization condition, and the condition under which the exposure amount and defocus amount are varied in the range of the specification of a predetermined lithographic process. Specifically, the OPC and verification tool 62 installed in the second verification module 39 outputs GDS (Graphic Data System) and the like including data on the design pattern 1 in the initial state, data on the design pattern 1 after the OPC process, and error data as the result of the final pattern verification. These pieces of output information are sent to a pattern modification tool 63 explained later and used in the final modification of the design pattern 1.

Here, the specification of the lithographic process is assumed to indicate that, for example, the focal depth is about within ±0.1 μm or the exposure amount allowance is within about ±10%. The OPC and verification tool 62 and the calculation condition used in the process of calculating the amount of gap in position should be the same as the tool and calculation condition used in the process of calculating a transfer image when a matching pattern is created by the matching pattern cutout tool 60.

Finally, the pattern modification tool 63 shown in FIG. 14 modifies the hotspot shown in Step 9 of FIG. 10. Specifically, first, the pattern modification tool 63 is installed in a second modification module 40 (described later) included in the pattern verification and design system 30 shown in the block diagram of FIG. 8. Then, the OPC and verification tool 62 installed in the second verification module 39 inputs to the pattern modification tool 63 the result of the OPC process and verification conducted by the OPC and verification tool 62, the data for the design pattern in the initial state, the data for the design pattern 1 after the OPC process, GDS, etc. These items of data include data on the layout of the design pattern 1 included in a small area around the hotspot partially cut out from the entire design pattern 1 by the pattern matching tool 60 of FIG. 12. Moreover, other specific modification rules are also input to the pattern modification tool 63. Then, the pattern modification tool 63 partially modifies the design pattern 1 on the basis of the modification rules.

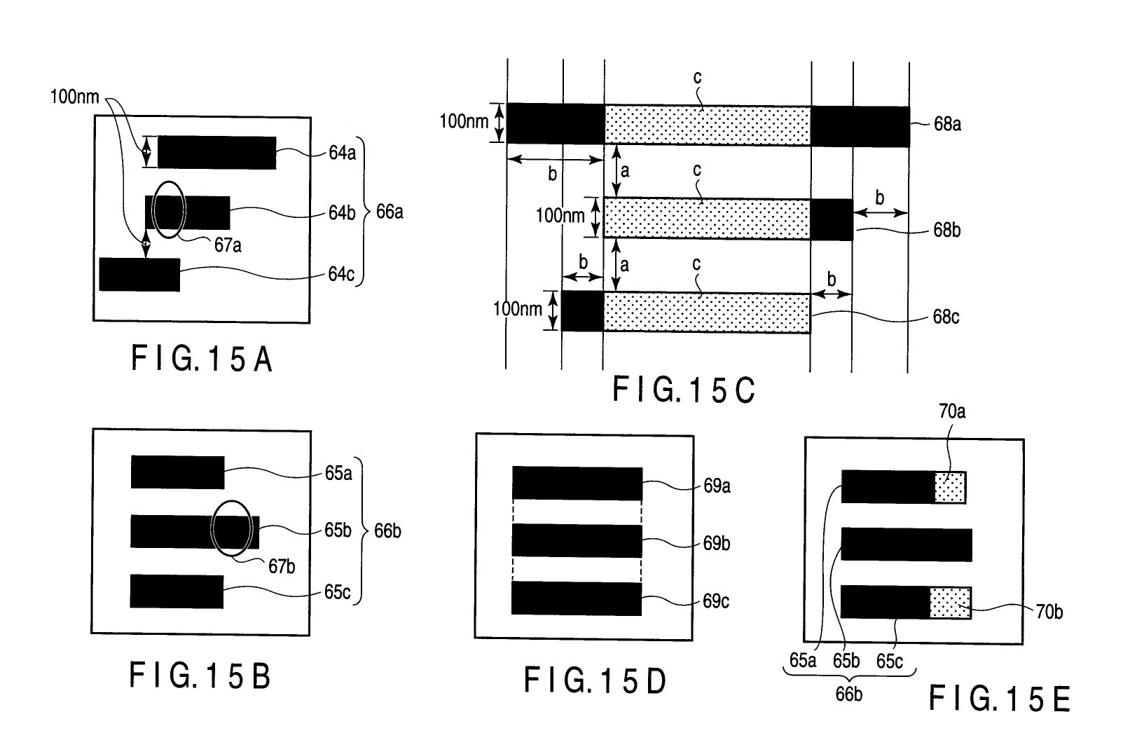

Specifically, on the basis of the modification rules, the pattern modification tool 63 modifies the hotspot detected by the OPC and verification tool 62 so as to satisfy the lithographic margin. Then, the pattern modification tool 63 outputs data on the partially modified design pattern 1. The modification rules used here are as shown in FIGS. 15A to 17B, explained below.

FIGS. 15A to 17B schematically show the modification rules in the pattern design method of the second embodiment. These rules are all related to operations performed on data.

First, FIGS. 15A and 15B show examples of design patterns 66a, 66b where three straight line patterns 64a, 64b, 64c and three straight line patterns 65a, 65b, 65c are arranged in parallel with one another in the longitudinal direction and errors (hotspots) 67a, 67b frequently occurring in the design patterns 66a, 66b. In FIGS. 15A and 15B, the parts enclosed with circles are spots where hotspots 67a, 67b are predicted to occur. As shown in FIGS. 15A and 15C, the width of each of the line patterns 64a, 64b, 64c, 65a, 65b, 65c is set to about 100 nm. As shown in FIG. 15A, the spacing between the individual line patterns 64a, 64b, 64c, 65a, 65b, 65c is set to about 100 nm.

In the design pattern 66a shown in FIG. 15A, a hotspot 67a occurs because both ends of the three line patterns 64a, 64b, 64c are out of alignment. In the design pattern 66b shown in FIG. 15B, a hotspot 67b occurs because, of the three line patterns 65a, 65b, 65c, the right end of the central line pattern 65b projects more than the right ends of the upper and lower line patterns 65a, 65b. Thus, rules (restrictions) on the sizes of the parts shown by a, b, c in FIG. 15C are applied to the design pattern 66a shown in FIG. 15A and the design pattern 66b shown in FIG. 15B, thereby modifying the patterns. In FIG. 15C, “a” indicates the interval (spacing) between the individual line patterns 68a, 68b, 68c adjacent to one another. Moreover, in FIG. 15C, “b” indicates the amount of gap in position between (amount of projection from) the ends of the individual line patterns 68a, 68b, 68c adjacent to one another. Furthermore, in FIG. 15C, “c” indicates the area of each of the dotted regions where the line patterns 68a, 68b, 68c overlap with one another in the direction in which they are arranged.

An ideal pattern shape of each of the design pattern 66a of FIG. 15A and the design pattern 66b of FIG. 15B is a pattern shape obtained by laying out the three line patterns 69a, 69b, 69c with both their ends alighted with one another as shown in FIG. 15D. Accordingly, for example, in the design pattern 66a of FIG. 15A, the 3-line group 4 at error level 1 of FIG. 3 referred to in the first embodiment is detected (extracted) as a critical spot. At the same time, suppose, as a result of the optical proximity correction (OPC) and the lithographic verification in the second embodiment, the 3-line group 4 has been determined to be a critical spot. In this case, the three line patterns 64a, 64b, 64c are subjected to pattern modification so as to align all of both their ends. Moreover, for example, in the design pattern 66b of FIG. 15B, the 3-line group 1f at error level 1 of FIG. 4 referred to in the first embodiment is detected (extracted) as a critical spot. At the same time, suppose, as a result of the optical proximity correction (OPC) and the lithographic verification in the second embodiment, the 3-line group 1f has been determined to be a critical spot. In this case, as shown in the dotted parts of FIG. 15E, the upper and lower line patterns 65a, 65c are subjected to pattern modification so as to extend their right ends to the right end of the central line pattern 65b to eliminate the step (gap in position) between the right ends of the three line patterns 65a, 65b, 65c. In FIG. 15E, the dotted parts are the modified extended parts 70a, 70b.

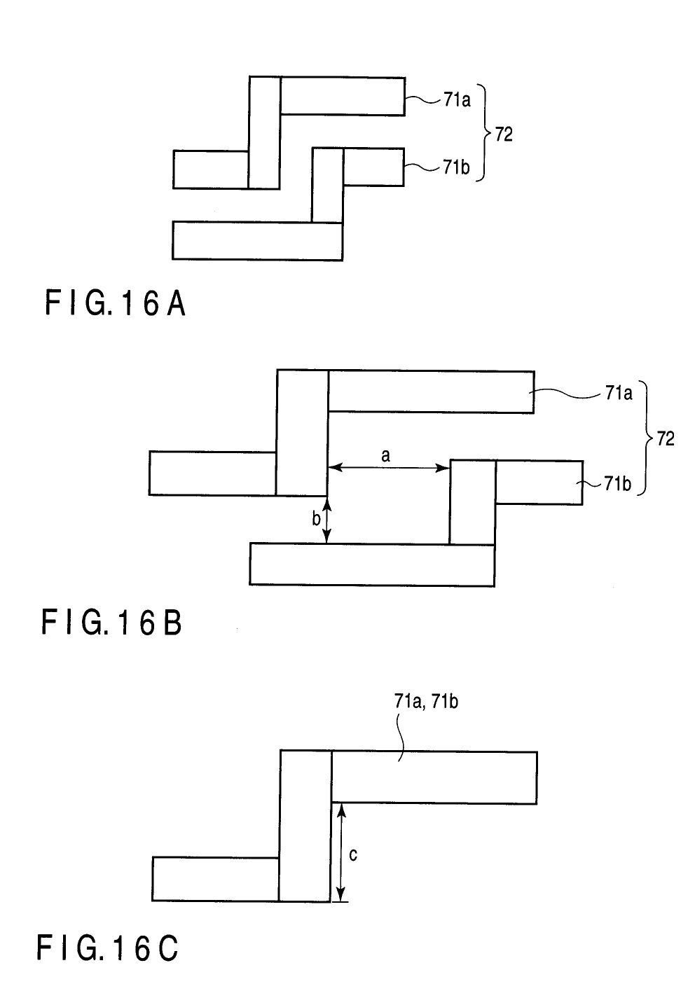

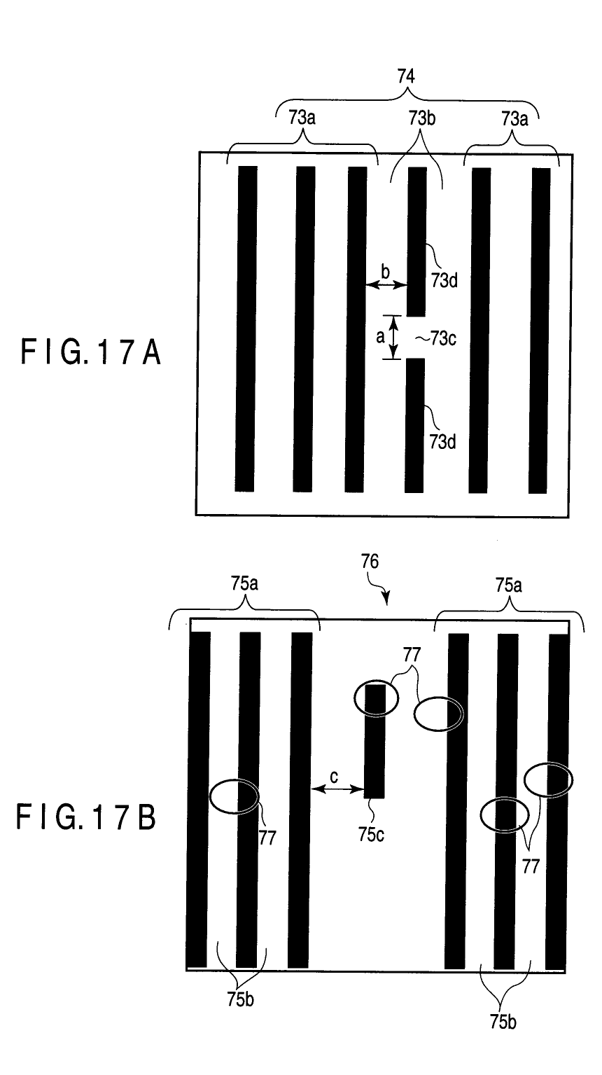

Next, FIG. 16A shows an example of a design pattern 72 obtained by laying out two cranked patterns 71a, 71b bent twice in the middle so as to be close to each other. Since the cranked patterns 71a, 71b are close to each other, the design pattern 72 includes a critical spot where a hotspot occurs. Accordingly, a limitation is imposed on the design pattern 72 to define the shortest distance of the interval (spacing) between the cranked patterns 71a, 71b shown by “a” and “b” in FIG. 16B, thereby modifying the design pattern 72. In the modification, the spacing between the cranked patterns 71a, 71b is modified suitably so as to prevent the cranked patterns 71a, 71b from coming too close to each other, thereby laying out the patterns 71a, 71b again. At the same time, a limitation is imposed on the pattern shape of the cranked patterns 71a, 71b to define the length of the cranked part shown by “c” in FIG. 16C, thereby modifying the patterns 71a, 71b.

Next, FIG. 17A shows an example of a design pattern 74 composed of a line-and-space pattern where a long line pattern 73a and a space pattern 73b are repeated regularly. Since there is an irregular small space pattern 73c in a part of the design pattern 74, this causes a hotspot, which becomes a problem. Accordingly, a restriction (limitation) is imposed on the length of the parts shown by “a” and “b” in FIG. 17A, thereby modifying the design pattern 74. Here, “a” in FIG. 17A represents the length of the space pattern 73c or the spacing between two short line patterns 73d designed so as to sandwich the space pattern 73c between them. Moreover, “b” in FIG. 17A represents the width of the space pattern 73b adjacent to two short line patterns 73d or the spacing between each of the line patterns 73d and the long line pattern 73a adjacent to each of the line patterns 73d. Specifically, in the design pattern 74, the spacing in the part shown by “a” in FIG. 17A is made shorter and the spacing in the part shown by “b” in FIG. 17A is made longer. This makes it possible to secure a sufficient process margin and prevent a hotspot from occurring.

In addition, FIG. 17B shows an example of a design pattern 76 composed of a line-and-space pattern where a long line pattern 75a and a space pattern 75b are repeated regularly. Since there is an irregular island-shaped isolated line pattern 75c in a part of the design pattern 76, this causes a hotspot, which becomes a problem. The part enclosed with a circle in FIG. 17B is an actual hotspot 77. Accordingly, a restriction (limitation) is imposed on the length of the part shown by “c” in FIG. 17B, thereby modifying the design pattern 76. Here, “c” in FIG. 17B represents the spacing between the isolated line pattern 75c and the long line pattern 75a adjacent to the isolated line pattern 75c. Specifically, the spacing in the part shown by “c” in FIG. 17B is made greater in the design pattern 76. This makes it possible to secure a sufficient process margin and prevent hotspots 77 from occurring.

As for the design patterns 66a, 66b, 72, 74, 76 explained with reference to FIGS. 15A to 15E, 16A to 16C, and 17A and 17B, the verification after the pattern matching has shown that there are many hotspots (critical spots) 67a, 67b, 77 all over the chip 28. However, all of the hotspots 67a, 67b, 77 do not necessarily require modification of the layout of the design patterns 66a, 66b, 72, 74, 76.

There are several types of patterns extracted as critical spots 67a, 67b, 77. For example, they include an original critical spot where the lithographic margin has not reached the allowable error region from the beginning, a critical spot where a deficiency in the lithographic margin will possibly be avoided by changing the method of the OPC process, and a critical spot where a deficiency in the lithographic margin will possibly be avoided by changing the placement rules for the individual functional blocks of a semiconductor integrated circuit or the routing rules for the individual functional blocks, or by changing the hardware rules and software rules. In the design patterns actually designed, such various critical spots are mixed.

In contrast, for example, in the design pattern 72 shown in FIG. 16A, by establishing a rule for the placement and routing (P & R), the occurrence of a hotspot will possibly be avoided. Whether the rule for P & R can be established is determined depending on whether a rule for the properties of the target P & R pattern and its ambient environment can be established. For example, in the design pattern 72, the occurrence of a hotspot can be avoided by recognizing the corners of the bent parts of the cranked patterns 71a, 71b and setting forbidden areas so as to prevent the ends of other patterns from being located around the corners.

Moreover, in the design patterns 74, 76 shown in FIGS. 17A and 17B, the occurrence of a hotspot 77 will possibly be avoided by setting again a target pattern to be subjected to OPC. The possibility of a change of the OPC method has been described above. If the OPC method has been changed once, all of the OPC and verification processes have to be carried out again. This results in an increase in the TAT (Turn Around Time) from the viewpoint of the total throughput required for the pattern design. Whether to change the OPC method depends on the situation. In contrast, if many patterns are registered in an error library (database), taking only TAT required for the OPC process into account, this will have the opposite effect of increasing the load on the pattern matching process.

Furthermore, an invalid pattern included in the design pattern 1o of FIG. 7 referred to in the first embodiment can be avoided by changing the placement and routing (P & R) rules. However, if the placement and routing rules are changed, the positions of the pins (vias) connecting interconnections might have to be set again or the lithographic margins of other patterns might be decreased due to adverse side-effects. Accordingly, it is difficult to establish so many rules for conditions in the actual manufacturing of semiconductor devices. Therefore, it is desirable not to change the OPC method or placement and routing (P & R) rules when an adverse effect on other patterns is expected. If a change of the OPC method or the establishment of the placement and routing rules is expected to have an adverse effect, it is desirable to modify the patterns by the method of the second embodiment.

Specifically, the invalid patterns 72, 74, 76 are registered in the library and a check is made to see if at least one of the invalid patterns 72, 74, 76 is included in the design pattern. If at least one of the invalid patterns 72, 74, 76 is included in the design pattern, the invalid pattern and an area about 3 μm around the invalid pattern are cut out, and the cut-out area is subjected to the OPC process and verification. If the result of the verification has shown that a critical spot is included in the design pattern, the design pattern is modified and the modified pattern and area about 3 μm around the modified pattern are output with a layer different from that of the unmodified pattern.

The technique explained with reference to FIGS. 15A to 15E, 16A to 16C, and 17A and 17B is an example of the modification rule in the pattern design method of the second embodiment.

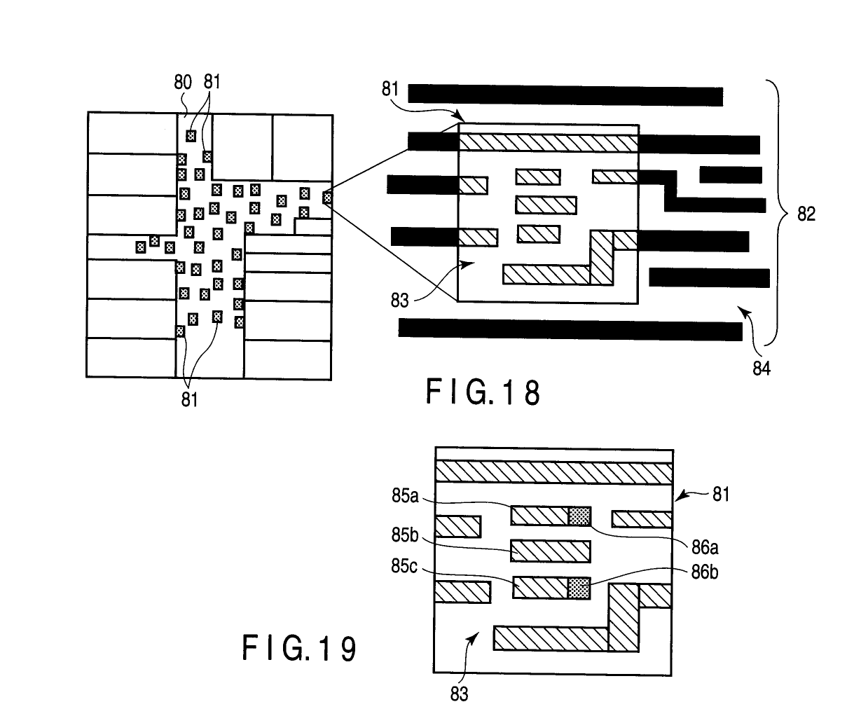

Next, FIGS. 18 and 19 schematically show an example of the result of modifying a design pattern by the pattern design method of the second embodiment.

First, as shown by a plurality of small box-shaped dotted parts at the left of FIG. 18, a critical spot 81 is detected from a semiconductor chip 80 through pattern matching in a simulation. As shown on the right side of FIG. 18, the detected critical spot 81 and a transfer pattern 82 included in its surrounding area are cut out of the semiconductor chip 80. The right side of FIG. 18 is an enlarged view of one of the critical spots 81 on at the left of FIG. 18 and its surrounding area. As shown by the hatched part at the right of FIG. 18, a critical pattern 8B included in the critical spot 81 of the transfer patterns 82 in the cut-out area is output with a different pattern into a layer different from that of a surrounding pattern 84 not including the black critical spot 81 at the right of FIG. 18. By switching between the layer and pattern output to the pattern 83 included in the critical spot 81 and those output to the pattern 84 not included in the critical spot 81, the OPC condition is relaxed in the OPC process after tape out in the area where verification and modification have been completed in the placement and routing stage, which enables the processes to be carried out quickly.

Next, the critical pattern 83 included in the cut-out critical spot 81 is modified according to a specific modification rule. As shown by the dotted parts in FIG. 19, the critical pattern 83 is modified as the design pattern if at error level 1 of FIG. 4 referred to in the first embodiment and the design pattern 66b of FIG. 15B referred to in the second embodiment are modified. Specifically, to eliminate a gap in position between the right ends of the three line patterns 85a, 85b, 85c in the central part of the critical pattern 83, the upper and lower line patterns 85a, 85c are modified by extending their right ends to the right end of the central line pattern 85b. The dotted parts in FIG. 19 are the extended parts 86a, 86b. Although not shown, the actual semiconductor chip product has a sufficient lithographic margin and process margin which enables a microscopic pattern almost free from hotspots, such as an open error or a short error, to be formed with high accuracy.

(Pattern Design System)

A pattern design system according to the second embodiment will be explained with reference to FIG. 8 referred to in the first embodiment. In the first embodiment, the pattern verification and design system 30 of FIG. 8 has been explained as a pattern verification system which implements the pattern verification method shown in the flowchart of FIG. 1. In contrast, in the second embodiment, the pattern verification and design system 30 will be explained as a pattern design system (pattern modification system) which implements the pattern design method (pattern modification method) shown in the flowchart of FIG. 10. The pattern design system 30 of the second embodiment makes use of the pattern verification system of the first embodiment. Specifically, as shown in FIG. 8, the pattern design system 30 of the second embodiment is so configured that a first pattern modification unit 41 which includes a first modification module 38, a second verification module 39, and a second modification module 40 enclosed with a dashed-dotted line in FIG. 8 is added to the pattern verification system of the first embodiment which includes a transfer information acquisition module 31, a first database creation module 32, a threshold value setting module 33, a second database creation module 34, a first verification module 35, and a pattern display module 36.

Hereinafter, a major difference between the pattern design system 30 of the second embodiment and the pattern verification system of the first embodiment will be explained. Accordingly, in the second embodiment, of the components included in the pattern verification and design system 30, a detailed explanation of the transfer information acquisition module 31, first database creation module 32, threshold value setting module 33, second database creation module 34, first verification module 35, and pattern display module 36 which have been explained in the first embodiment will be omitted. Of the first and second pattern modification units 41, 46 included in the pattern verification and design system 30 which have not been explained in the first embodiment, the second pattern modification unit 46 will be explained in the third embodiment later. In the second embodiment, the function of the first pattern modification unit 41 will be mainly explained. With this explanation, explanation of the functions of the entire pattern design system 30 of the second embodiment is assumed as having been given. It is assumed that, of the components of the pattern design system 30 of the second embodiment and their functions, those not explained in the second embodiment are the same as the components and their functions included in the pattern verification system of the first embodiment.

As explained with reference to FIGS. 1 to 8 in the first embodiment, the transfer information acquisition module 31, first database creation module 32, threshold value setting module 33, second database creation module 34, first verification module 35, and pattern display module 36 execute Step 1 to Step 6 of the pattern design method shown in the flowchart of FIG. 10. Then, as shown in FIG. 8, the first verification module 35 sends data 37 on the result of pattern matching to the first modification module 38 of the first pattern modification unit 41 instead of outputting the data 37 outside the pattern design system 30. That is, in the second embodiment, unlike in the first embodiment, the first verification module 35 does not execute Step 7 in the flowchart of FIG. 1.

Using data 37 on the result of pattern matching received from the first verification module 35 and the OPC and verification tool 62 of FIG. 13, the first modification module 38 executes a pre-process in Step 8 shown in the flowchart of FIG. 10. That is, if the data 37 includes an invalid pattern that does not satisfy the threshold value for the feature quantity, the first verification module 38 carries out a first pattern verification process so that the invalid pattern may satisfy the threshold value for the feature quantity. Specifically, the first modification module 38 extracts an invalid pattern included in the data 37 and a transfer pattern included in an area surrounding the invalid pattern and subjects the surrounding area including the invalid pattern to local optical proximity correction (OPC) so that the lithographic margin of the invalid pattern may reach the allowable error margin. After carrying out the OPC process, the first modification module 38 sends the result to the second verification module 39 of the first pattern modification unit 41.

As described above, instead of optical proximity correction, for example, process proximity correction (PPC) may be performed as the pattern modification in Step 8. The first modification module 38 is also referred to as a first pattern modification module or a proximity correction module.

Using the result of the OPC process received from the first modification module 38 and the OPC and verification tool 62 shown in FIG. 13, the second verification module 39 executes the post-process in Step 8 shown in the flowchart of FIG. 10. That is, the second verification module 39 verifies whether the pattern in the area subjected to the OPC process satisfies the threshold value for the feature quantity. Specifically, the second verification module 39 acquires again a transfer image of the pattern in the area subjected to the OPC process and subjects the transfer image to lithographic verification. Then, after conducting the lithographic verification, the second verification module 39 sends the result to the second modification module 40 included in the first pattern modulation unit 41.

Using the result of the lithographic verification received from the second verification module 39 and the pattern modification tool 63 of FIG. 14, the second modification module 40 executes Step 9 shown in the flowchart of FIG. 10. Specifically, if the result of the lithographic verification conducted by the second verification module 39 has shown that a hotspot which does not satisfy the threshold value for the feature quantity has been detected in the area subjected to the OPC process by the first modification module 38, the second modification module 40 acquires the transfer image of the surrounding area including the hotspot. On the basis of the result of the verification of the acquired transfer image, the second modification module 40 subjects the hotspot in the design pattern to a second pattern modification so that the hotspot may satisfy the threshold value for the feature quantity. Specifically, the second modification module 40 extracts the hotspot and a transfer pattern included in an area surrounding the hotspot and modifies the hotspot so that the lithographic margin of the hotspot may reach the allowable error margin. The second modification module 40 is also referred to as a second pattern modification module.

Furthermore, the first pattern modification unit 41 composed of the first modification module 38, second verification module 39, and second modification module 40 carries out Step 10 shown in the flowchart of FIG. 10. That is, as shown by a solid-line arrow in an area enclosed with a dashed-dotted line in FIG. 8, the first modification module 38, second verification module 39, and second modification module 40 carry out a modification and verification cycle composed of the processes in Step 8 and Step 9 repeatedly a plurality of times until the entire surface of the semiconductor substrate 28 has been modified. Specifically, the first modification module 38, second verification module 39, and second modification module 40 subject all the design patterns 1 formed on the semiconductor substrate 28 to the OPC process, lithographic verification, and hotspot modification.

Then, as shown in FIG. 8, the second verification module 39 checks (verifies) whether an invalid spot has disappeared from the design pattern subjected to the OPC process, lithographic verification, and hotspot modification. After checking that an invalid spot has disappeared from the design pattern 1, the second verification module 39 outputs the result as data on the final design pattern 42 for actually manufacturing products outside the pattern design system 30.

Thereafter, a semiconductor device manufacturing apparatus and a semiconductor device test apparatus (both not shown) different from the pattern design system 30 execute Step 11 shown in the flowchart of FIG. 10 on the basis of data on the final design pattern 42 output outside the pattern design system 30. That is, on the basis of data on the final design pattern 42, the semiconductor device manufacturing apparatus produces in large quantities a semiconductor chip 28 provided with the layout of the individual functional blocks of the semiconductor integrated circuit and the interconnections between the functional blocks. Then, the semiconductor device test apparatus examines whether each of the produced semiconductor chips 28 operates as planned.

(Pattern Design Program)

Next, a pattern design program (pattern modification program) according to the second embodiment and a computer-readable recording medium 51 in which the pattern design program has been recorded will be explained with reference to FIG. 9 referred to in the first embodiment. Like the pattern verification program and recording medium in the first embodiment, the pattern design program and recording medium 51 in the second embodiment not only operates the pattern design system 30 of FIG. 8 but also controls its operation, thereby implementing the pattern design method shown in the flowchart of FIG. 10. The pattern design program of the second embodiment makes use of the pattern verification program of the first embodiment as the pattern design system 30 of the second embodiment makes use of the pattern verification system of the first embodiment. Furthermore, in the second embodiment, it is assumed that the pattern design program of the second embodiment has been recorded in the recording medium 51 of FIG. 9 instead of the pattern verification program of the first embodiment.

Hereinafter, a major difference between the pattern design program and recording medium 51 of the second embodiment and the pattern verification program and recording medium of the first embodiment will be explained. It is assumed that, of the advantages the pattern design program and recording medium 51 of the second embodiment have, those not explained are the same as the advantages the pattern verification program and recording medium of the first embodiment have.

Of the individual steps included in the pattern design method of the second embodiment shown in the flowchart of FIG. 10, Step 8 to Step 10 are basically composed of data processing steps that the computer 50 of FIG. 9 can process as Step 1 to Step 6 explained in the first embodiment. Accordingly, like the pattern verification method of the first embodiment, the pattern design method of the second embodiment can also be implemented by the pattern design system 30 realized by the computer 50 whose operation is controlled by reading the pattern design program of the second embodiment recorded in the recording medium 51. Hereinafter, an explanation will be given regarding the pattern design system 30 of FIG. 8 as the computer 50 of FIG. 9.

In the second embodiment, like in the first embodiment, the input sections of the first modification module 38, second verification module 39, and second modification module 40 included in the first pattern modification unit 41 of FIG. 8 are treated collectively as an input module 52 of the computer 50 of FIG. 9. Similarly, the output sections of the first modification module 38, second verification module 39, and second modification module 40 are treated collectively as an output module 53 of the computer 50 of FIG. 9. Moreover, the storage sections of the first modification module 38, second verification module 39, and second modification module 40 are treated collectively as a storage module 54 of the computer 50 of FIG. 9. Furthermore, the arithmetic processing sections of the first modification module 38, second verification module 39, and second modification module 40 are treated collectively as a CPU (arithmetic processing module) 55 of the computer 50 of FIG. 9.

First, as shown in FIG. 9, the pattern design program recorded in the recording medium 51 is read into the computer 50. Specifically, the CPU 55 is caused to read the pattern design program recorded in the recording medium 51 via the input module 52 of the computer 50. The pattern design program read by the CPU 55 is sent to the storage module 54 of the computer 50, which stores the program. Thereafter, the CPU 55 operates the computer 50 suitably on the basis of the pattern design program stored in the storage module 54 so that the pattern design system 30 may implement the pattern design method properly. That is, the pattern design program causes the transfer information acquisition module 31, first database creation module 32, threshold value setting module 33, second database module 34, first verification module 35, pattern display module 36, first modification module 38, second verification module 39, and second modification module 40 in the pattern design system 30 to operate suitably so that the pattern design system 30 may implement the pattern design method properly as explained with reference to FIGS. 8 and 10.

After a series of pattern design processes has been completed, the result of the processes are output as data 42 on the final design pattern via the output module 53 of the computer 50 (pattern design system 30) outside the computer 50 as shown in FIG. 8. At this time, the result of the pattern design process performed by the computer 50 may also be stored in the storage module 54. As described above, the pattern design system 30 of the second embodiment is realized properly by not only reading the pattern design program recorded in the recording medium 51 into the computer 50 but also causing the read-in pattern design program to control the operation of the computer 50. The pattern design method of the second embodiment is implemented properly by the pattern design system 30 acting as the computer 50 which has read in the pattern design program recorded in the recording medium 51.

As described above, making use of the pattern verification method, pattern verification system, and pattern verification program of the first embodiment, the second embodiment produces the same effect as the first embodiment. In addition, with the second embodiment, those design patterns 1 in an area already modified and verified of all the design patterns 1 formed on the semiconductor substrate 28 can be processed with a decreased number of iterations of OPC. As a result, the processing time of OPC after tape out is shortened and therefore the total design time from the design to the post process in the pattern design process shown in the flowchart of FIG. 10 can be shortened. Therefore, according to the second embodiment, it is possible to provide a pattern design system method, a pattern design system, and pattern design program which are capable of forming microscopic patterns efficiently with high accuracy.

### Third Embodiment

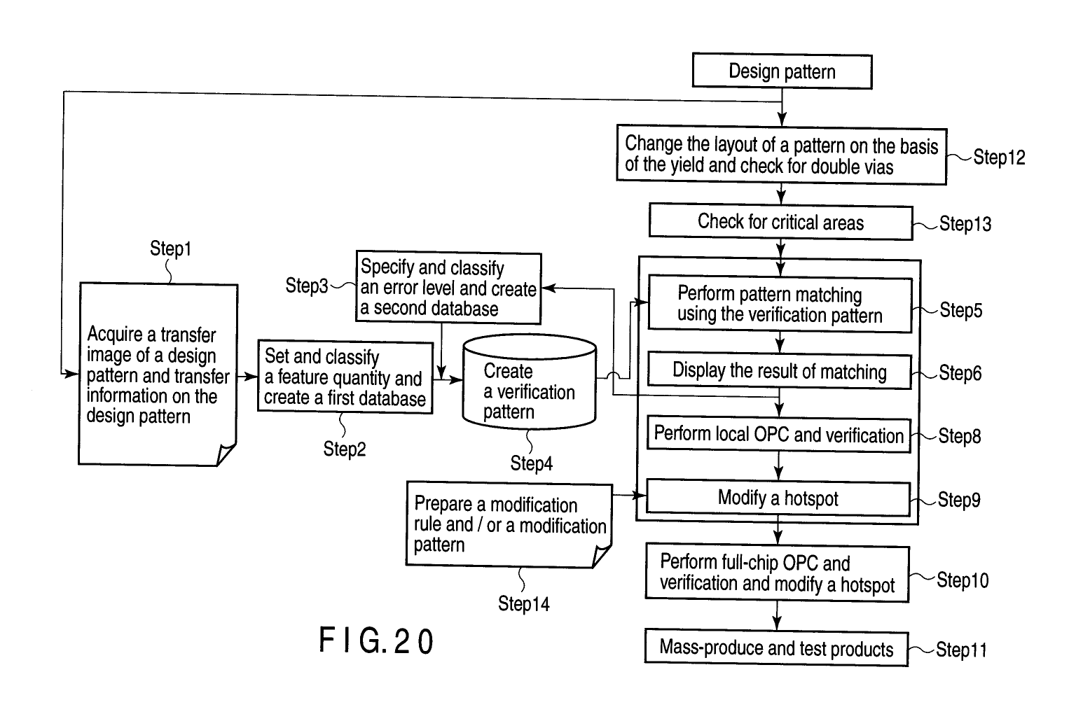

Next, a third embodiment of the invention will be explained mainly with reference to FIG. 20. In the third embodiment, the same parts as those of the first and embodiments are indicated by the same reference numerals and a detailed explanation of them will be omitted.

The third embodiment relates to a pattern design method, a pattern design system, and a pattern design program which make use of the pattern verification method, pattern verification system, and pattern verification program of the first embodiment and the pattern design method, pattern design system, and pattern design program of the second embodiment, respectively. The third embodiment differs greatly from the first and second embodiments in that the third embodiment includes the process of changing the layout of a pattern before verifying a design pattern, taking into account information on defects in the pattern.

(Pattern Design Method)

Hereinafter, a pattern design method according to the third embodiment will be explained in detail with reference to FIG. 20.

In the pattern design method of the third embodiment, as shown in a flowchart in FIG. 20, first, Step 1 to Step 6 and Step 8 to Step 11 are carried out as in the pattern design method of the second embodiment of FIG. 10. In the third embodiment, however, the following two processes are carried out before the design pattern 1 is subjected to pattern matching in Step 5.

First, taking into account information on defects included in the design pattern 1, the layout of the design pattern 1 is changed. That is, the layout of the individual patterns included in the design pattern 1 is changed on the basis of the yield resulting from defects included in the design pattern 1. Specifically, to improve the yield, the spacing between wiring patterns included in the design pattern 1 is made wider (wire spreading) or a via-pattern that connects interconnections electrically is changed from a single via to a double via. At the same, a check is made to see if these changes have been made properly (Step 12).

Next, a check is made to see if a critical area (CA) is included in the spot changed in Step 12 (Step 13).

The data for the design pattern 1 checked in Step 13 is subjected to pattern matching in Step 5. Accordingly, in the third embodiment, unlike in the first and second embodiments, whether the transfer pattern based on the design pattern 1 satisfies the threshold value is not determined by the comparison between the design pattern 1 in the original state (or in the initial state) immediately after it is designed and the transfer pattern based on the design pattern 1. In the third embodiment, whether the transfer pattern based on the design pattern 1 satisfies the threshold value is determined by the comparison between the design pattern 1 from which an invalid pattern (error) has been removed and the transfer pattern based on the design pattern 1 in the initial state.

As described above, before the design pattern 1 is subjected to pattern matching in Step 5, the processes in Step 12 and Step 13 are carried out, thereby taking measures against random errors in the design pattern 1. Thereafter, the data for the design pattern 1 subjected to the processes in Step 12 and Step 13 is subjected to pattern matching in Step 5. Then, as in the second embodiment, the processes in Step 5, Step 7, and Step 8 to Step 11 shown in the flowchart of FIG. 20 are executed.

In the pattern design of the third embodiment, at least either the modification rule or the modification pattern is prepared beforehand and referred to when a hotspot is modified in Step 9 as shown in the flowchart of FIG. 20 (Step 14).

This completes the pattern design method of the third embodiment. Generally, when the pattern layout is changed to take measures against random errors, there may be a case where a so-called systematic error occurs in the changed pattern layout. In contrast, with the GDS related to Step 12 and Step 13 of the third embodiment, there are no spots causing new systematic errors undetected after measures have been taken against random errors. That is, with the third embodiment, a random error can be eliminated from the design pattern 1 before the processes in Step 5, Step 6, and Step 8 to Step 11 shown in the flowchart of FIG. 20 are executed. Moreover, not only random errors but also systematic errors can be removed from the design pattern 1.

(Pattern Design System)

Next, a pattern design system according to the third embodiment will be explained with reference to FIG. 8 referred to in the first and second embodiments. In the third embodiment, like in the second embodiment, the pattern verification and design system 30 of FIG. 8 will be explained as a pattern design system (pattern modification system) which implements the pattern design method (pattern modification method) shown in the flowchart of FIG. 20. The pattern design system 30 of the third embodiment makes use of not only the pattern verification system of the first embodiment but also the pattern design system of the second embodiment. Specifically, as shown in FIG. 8, the pattern design system 30 of the third embodiment is so configured that a second pattern modification unit 46 which includes a third modification module 43, a third verification module 44, and a modification policy decision module 45 shown in FIG. 8 is added to not only the pattern verification system of the first embodiment which includes a transfer information acquisition module 31, a first database creation module 32, a threshold value setting module 33, a second database creation module 34, a first verification module 35, and a pattern display module 36 but also the first pattern modification unit 41 which includes a first modification module 38, a second verification module 39, and a second modification module 40 enclosed with a dashed-dotted line in FIG. 8.

Hereinafter, a major difference between the pattern design system 30 of the third embodiment and not only the pattern verification system of the first embodiment but also the pattern design system of the second embodiment will be mainly explained. Accordingly, in the third embodiment, of the components included in the pattern verification and design system 30, a detailed explanation will be omitted as to the transfer information acquisition module 31, first database creation module 32, threshold value setting module 33, second database creation module 34, first verification module 35, and pattern display module 36 which have been explained in the first embodiment and the first pattern modification unit 41 of the second embodiment composed of the first modification module 38, second verification module 39, and second modification module 40 which have been explained in the second embodiment. In the third embodiment, the function of the second pattern modification unit 46 will be mainly explained. With this explanation, the function of the entire pattern design system 30 of the third embodiment will be assumed to have been explained. It is assumed that the components of the pattern design system 30 of the third embodiment and their functions, those not explained in the third embodiment are the same as the components and their functions included in the pattern verification system of the first embodiment and the pattern design system of the second embodiment.

First, as shown in FIG. 8, in parallel with the time when the transfer information acquisition module 31 acquires data for the design pattern 1, the third modification module 43 also acquires data for the design pattern 1. Having acquired the data for the design pattern 1, the third modification module 43 executes a pre-process in Step 12. That is, the third modification module 43 not only widens the spacing between wiring patterns included in the design pattern 1 but also changes the via pattern electrically connecting the interconnections from a single via to a double via. After having changed the layout of the patterns included in the design pattern 1, the third modification module 43 sends the changed data to the third verification module 44.

After receiving the changed data for the design pattern 1, the third verification module 44 executes a post-process in Step 12 and a process in Step 13 shown in the flowchart of FIG. 20. That is, the third verification module 44 checks whether the third modification module 43 has made a change properly and further checks whether a critical spot is included in the spot changed by the third modification module 43. After completing the checks, the third verification module 44 sends the checked data for the design pattern 1 to the first verification module 35.

Accordingly, in the third embodiment, unlike in the first and second embodiments, the first verification module 35 compares the design pattern 1 modified by the third modification module 43 with the transfer pattern based on the design pattern 1 in the initial state not modified by the third modification module 43, thereby performing pattern matching to see if the transfer pattern satisfies the threshold value. The third modification module 43 and third verification module 44 carry out the processes in Step 12 and Step 13 in parallel with the time when the transfer information acquisition module 31, first database creation module 32, threshold value setting module 33, and second database creation module 34 of the first embodiment carry out the processes in Step 1 to Step 4.

When the second modification module 40 modifies a hotspot in Step 9, the modification policy decision module 45 executes Step 14 shown in the flowchart of FIG. 20. That is, the modification policy decision module 45 sends data on at least either a rule or a pattern for modification of previously held hotspots to the second modification module 40. After receiving data on at least either a rule or a pattern for modification of previously held hotspots from the modification policy decision module 45, the second modification module 40 modifies a hotspot in Step 9, referring to the data.

(Pattern Design Program)

Next, a pattern design program (pattern modification program) according to the third embodiment and a computer-readable recording medium 51 in which the pattern design program has been recorded will be explained with reference to FIG. 9 referred to in the first and second embodiments. Like the pattern verification program and recording medium in the first embodiment and the pattern design program and recording medium in the second embodiment, the pattern design program and recording medium 51 in the third embodiment not only operate the pattern design system 30 of FIG. 8 but also control its operation, thereby implementing the pattern design method shown in the flowchart of FIG. 20. The pattern design program of the third embodiment makes use of the pattern verification program of the first embodiment and the pattern design program of the second embodiment as the pattern design system 30 of the third embodiment makes use of the pattern verification system of the first embodiment and the pattern design system of the second embodiment. Furthermore, in the third embodiment, it is assumed that the pattern design program of the third embodiment has been recorded in the recording medium 51 of FIG. 9 instead of the pattern verification program of the first embodiment and the pattern design program of the second embodiment.

Hereinafter, a major difference between the pattern design program and recording medium 51 of the third embodiment and not only the pattern verification program and recording medium of the first embodiment but also the pattern design program and recording medium of the second embodiment will be mainly explained. It is assumed that, of the advantages the pattern design program and recording medium 51 of the third embodiment have, those not explained are the same as the advantages not only the pattern verification program and recording medium of the first embodiment but also the pattern design program and recording medium of the second embodiment have.

Of the individual steps included in the pattern design method of the third embodiment shown in the flowchart of FIG. 20, Step 12 to Step 14 are basically composed of data processing steps that the computer 50 of FIG. 9 can process as Step 1 to Step 6 explained in the first embodiment and Step 8 to Step 10 explained in the second embodiment. Accordingly, like the pattern verification method of the first embodiment and the pattern design method of the second embodiment, the pattern design method of the third embodiment can also be implemented by the pattern design system 30 realized by the computer 50 whose operation is controlled by reading the pattern design program of the third embodiment recorded in the recording medium 51. Hereinafter, an explanation will be given regarding the pattern design system 30 of FIG. 8 as the computer 50 of FIG. 9.

In the third embodiment, like in the first and second embodiments, the input sections of the third modification module 43, third verification module 44, and modification policy decision module 45 included in the second pattern modification unit 46 of FIG. 8 are treated collectively as an input module 52 of the computer 50 of FIG. 9. Similarly, the output sections of the third modification module 43, third verification module 44, and modification policy decision module 45 are treated collectively as an output module 53 of the computer 50 of FIG. 9. Moreover, the storage sections of the third modification module 43, third verification module 44, and modification policy decision module 45 are treated collectively as a storage module 54 of the computer 50 of FIG. 9. Furthermore, the arithmetic processing sections of the third modification module 43, third verification module 44, and modification policy decision module 45 are treated collectively as a CPU (arithmetic processing module) 55 of the computer 50 of FIG. 9.

First, as shown by an outline arrow in FIG. 9, the pattern design program recorded in the recording medium 51 is read into the computer 50. Specifically, the CPU 55 is caused to read the pattern design program recorded in the recording medium 51 via the input module 52 of the computer 50. The pattern design program read by the CPU 55 is sent to the storage module 54 of the computer 50, which stores the program. Thereafter, the CPU 55 operates the computer 50 suitably on the basis of the pattern design program stored in the storage module 54 so that the pattern design system 30 may implement the pattern design method properly. That is, the pattern design program causes the transfer information acquisition module 31, first database creation module 32, threshold value setting module 33, second database module 34, first verification module 35, pattern display module 36, first modification module 38, second verification module 39, and second modification module 4, third modulation module 43, third verification module 44, and modulation policy decision module 45 in the pattern design system 30 to operate suitably so that the pattern design system 30 may implement the pattern design method properly as explained with reference to FIGS. 8 and 20.

After a series of pattern design processes has been completed, the result of the processes is output as data 42 on the final design pattern via the output module 53 of the computer 50 (pattern design system 30) outside the computer 50 as shown in FIG. 8. At this time, the result of the pattern design process performed by the computer 50 may also be stored in the storage module 54. As described above, the pattern design system 30 of the third embodiment is realized properly by not only reading the pattern design program recorded in the recording medium 51 into the computer 50 but also causing the read-in pattern design program to control the operation of the computer 50. The pattern design method of the third embodiment is implemented properly by the pattern design system 30 acting as the computer 50 which has read in the pattern design program recorded in the recording medium 51.

As described above, making use of the pattern verification method, pattern verification system, and pattern verification program of the first embodiment and the pattern design method, pattern design system, and pattern design program of the second embodiment, the third embodiment produces the same effects as the first and second embodiments. In addition, in the pattern design process of the third embodiment, since an invalid pattern detecting process and a pattern replacing process have been carried out before pattern matching, the processing time can be reduced remarkably as compared with that in the pattern design process of the second embodiment.

Furthermore, with the third embodiment, in the area where patterns have been verified, the OPC condition and verification condition in the post-process can be eased by replacing the layer number with the layer number before the verification. This makes it possible to decrease the number of iterations of OPC and verification remarkably. Moreover, in the third embodiment, since random errors and systematic errors caused by the lithographic margin can be eliminated beforehand, critical spots which will become a problem in a post-process can be reduced remarkably. That is, in the third embodiment, since the process of modifying a pattern again can be eliminated, the total pattern design time required to lay out element blocks in the pattern design stage, provide interconnections between the individual elements, and carry out the post-process can be shortened remarkably.

Therefore, according to the third embodiment, it is possible to provide a pattern design system method, a pattern design system, and pattern design program which are capable of forming microscopic patterns more efficiently and with high accuracy.

### Fourth Embodiment

Next, a fourth embodiment of the invention will be explained without giving a diagrammatic representation. In the fourth embodiment, the same parts as those in the first to third embodiments are indicated by the same reference numerals and a detailed explanation of them will be omitted. In the fourth embodiment, a mask manufacturing method characterized by using the technique related to either the second or the third embodiment will be explained.

First, using the technique related to either the second or the third embodiment, data for a design pattern 1 of a semiconductor integrated circuit which includes neither an invalid pattern nor a hotspot and has a sufficient lithographic margin and a process margin is created. Then, on the basis of the data for the design pattern (modified transfer pattern) 1 which satisfies such a threshold value, a pattern is drawn and formed on mask blanks using an exposure device. This makes it possible to create an exposure mask with a desired mask pattern which enables a microscopic pattern to be transferred and formed on a semiconductor substrate 28 with high accuracy.

As described above, since the technique related to either the second or the third embodiment is used, the fourth embodiment produces the same effects as the second and third embodiments. That is, according to the fourth embodiment, it is possible to provide a mask manufacturing method capable of forming microscopic patterns efficiently and with high accuracy.

### Fifth Embodiment

Next, a fifth embodiment of the invention will be explained without giving a diagrammatic representation. In the fifth embodiment, the same parts as those in the first to fourth embodiments are indicated by the same reference numerals and a detailed explanation of them will be omitted. The fifth embodiment relates to the technique for manufacturing a semiconductor device by using at least one of the pattern verification method, pattern verification system, and pattern verification program of the first embodiment, the pattern design method, pattern design system, and pattern design program of the second embodiment, the pattern design method, pattern design system, and pattern design program of the third embodiment, and the exposure mask of the fourth embodiment. As described above, the exposure mask of the fourth embodiment is basically formed by using the technique of the first embodiment and the technique related either to the second or the third embodiment. In the fifth embodiment, the technique for manufacturing a semiconductor device using the exposure mask of the fourth embodiment will be explained.

First, using the exposure mask of the fourth embodiment, a mask pattern is transferred to a resist film on a semiconductor substrate 38 and the resist film is developed, thereby forming a resist pattern on the resist film. Then, the processed film and semiconductor substrate 28 under the resist film are processed by etching or the like according to the resist pattern formed on the resist film. This makes it possible to form a desired microscopic pattern on the processed film and semiconductor substrate 28 with high accuracy. Thereafter, the semiconductor substrate 28 on which the pattern has been formed is subjected to a transistor manufacturing process, an interconnection forming process, a dicing process, a chip mounting process, a bonding process, a molding process, and other processes. This completes a desired semiconductor device (not shown) of the fifth embodiment.

As described above, in the fifth embodiment, a pattern is transferred using the exposure mask of the fourth embodiment. With this pattern transfer, a microscopic pattern can be formed with high accuracy, which enables various microscopic semiconductor elements, interconnections, and the like to be formed easily on a semiconductor substrate and the like efficiently and with high accuracy. Accordingly, a high-quality semiconductor device on which patterns have been formed with high accuracy and whose performance, reliability, quality, yield, etc. have been improved can be manufactured efficiently with ease.

The pattern verification method, pattern verification system, pattern verification program, computer-readable recording medium in which the pattern verification program has been recorded, the pattern design method, pattern design system, pattern design program, computer-readable recording medium in which the pattern design program has been recorded, the mask manufacturing method, and the semiconductor device manufacturing method are not restricted to the first to fifth embodiments. Their configuration or a part of the manufacturing process may be set variously or various settings may be combined suitably as needed without departing from the spirit of essential character of the invention.

For instance, the types of hotspots explained in the first embodiment are not limited to those shown in FIGS. 3 to 7. The types of hotspots change variously according to the degree of error, process conditions, the type of manufactured products, and other factors. Since a transfer image of the design pattern 1 is updated each time a manufactured product changes, setting should be so performed that the history of such transfer images is accumulated in the first and second databases. The error level setting method is not restricted to the condition explained in the first embodiment. The criterion for verification by pattern matching is not limited to the amount of gap in position and the dimensions of a transfer pattern shown in FIG. 2. The error levels, hotspots, and matching patterns in the first embodiment may be changed and selected suitably as needed each time data is verified. Moreover, the threshold value for the difference between the transfer image and the design pattern 1, that is, the degree of a hotspot, is actually specified by the properties of the pattern. The properties of the pattern specifically include a corner part, a line end, and a T-junction part.

The types of critical spots 81 explained in the second embodiment are not limited to those shown in FIG. 18. The types of critical spots differ depending on the generation of manufactured devices or the layer to be processed. The condition for verification by an OPC process or pattern matching is not restricted to what has been explained in the second embodiment. While in the second embodiment an area about 3 μm around a hotspot has been cut out in carrying out the pattern modification process, the cutout range of the surrounding area is not limited to about 3 μm. The size of the cutout area may be set to various values, provided that the size is equal to or larger than the optical radius of the optical system used in the exposure device. Moreover, in the second embodiment, to make it easier to distinguish between a modified design pattern 1 and an unmodified design pattern 1, they have been output in such a manner that their layers are made different from one another. However, it goes without saying that the modified pattern and the unmodified pattern may be output to the same layer.

While in the second embodiment the modification rule has been used in modifying the design pattern 1, the invention is not limited to this method. For instance, a modified design pattern may be prepared beforehand. If a hotspot has been detected in an unmodified design pattern 1 through pattern verification, the part of the hotspot may be replaced with the modified pattern after the verification. With such a method, the modification work is virtually a pattern replacement work, which helps shorten the processing time more.

Furthermore, in the first and second embodiments, the feature quantity related to the invention has been defined as, for example, the amount of difference in dimensions between the dimensions of the design pattern and dimensional information included in the pattern transfer information or the amount of difference in area between the shape of the design pattern and shape information included in the pattern transfer information. That is, the feature quantity has been defined as the difference in dimensions or area between the design pattern and a transfer pattern corresponding to the design pattern. However, the feature quantity related to the invention is not limited to those definitions. In addition to those definitions, the feature quantity may be defined as the amount of gap in position between, for example, the corresponding edge parts of the design pattern and pattern transfer information. Moreover, the feature quantity may be defined as, for example, distance information or pattern-included information existing between pattern transfer information and a design pattern other than the corresponding design pattern. Specifically, the feature quantity may be defined as a quantity whereby pattern transfer information corresponds to a specific wiring pattern and design patterns other than the corresponding design pattern correspond to via patterns (hole patterns connecting interconnections).

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern verification method comprising:
acquiring information on a transfer pattern created from a design pattern corresponding to a pattern to be formed on a substrate as pattern transfer information;
comparing the design pattern with the transfer pattern;
classifying the pattern transfer information and the design pattern on the basis of the feature quantity obtained from the comparison;
setting a threshold value for the feature quantity;
further classifying on the basis of the threshold value the pattern transfer information and the design pattern classified on the basis of the feature quantity; and
verifying whether the transfer pattern satisfies the threshold value.

2. The pattern verification method according to claim 1, wherein the pattern transfer information is acquired through simulation.

3. The pattern verification method according to claim 1, wherein the pattern transfer information includes shape information on and dimension information on a pattern to be formed on the substrate.

4. The pattern verification method according to claim 1, wherein the feature quantity includes the amount of difference in area between the shape of the design pattern and the shape of the transfer pattern and the amount of difference in dimensions between the dimensions of the design pattern and the dimensions of the transfer pattern.

5. The pattern verification method according to claim 1, wherein a first database including the pattern transfer information and the design pattern classified on the basis of the feature quantity is updated each time the design pattern is updated and a history of the first database updated is accumulated.

6. The pattern verification method according to claim 1, wherein the threshold value is classified according to the type of the feature quantity and the type of the transfer pattern.

7. The pattern verification method according to claim 6, wherein the type of the transfer pattern includes a line end, a corner, and a T-junction.

8. The pattern verification method according to claim 6, wherein a second database including the pattern transfer information and the design pattern classified on the basis of the threshold value are hierarchized on the classified threshold value basis.

9. The pattern verification method according to claim 8, wherein the pattern transfer information and the design pattern belonging to a hierarchy level satisfying the condition for performing the verification are selected from the second database and the pattern transfer information and the design pattern selected are used in the verification.

10. The pattern verification method according to claim 1, wherein the threshold value is set to a specific level according to the design method for the design pattern.

11. The pattern verification method according to claim 1, wherein verification is conducted to see if the transfer pattern satisfies the threshold value, and
if the transfer pattern does not satisfy the threshold value, the transfer pattern which does not satisfy the threshold value is highlighted.

12. The pattern verification method according to claim 1, wherein verification is conducted to see if the transfer pattern satisfies the threshold value, and
if the transfer pattern does not satisfy the threshold value, the level of the threshold value of, a transfer image of, and a marker of the transfer pattern which does not satisfy the threshold value are displayed so as to be superimposed on the transfer pattern.

13. The pattern verification method according to claim 1, wherein the transfer pattern which does not satisfy the threshold value is composed of a single figure or a plurality of figures.

14. A computer-readable medium with a pattern verification program, the pattern verification program causing the computer to perform:
acquiring information on a transfer pattern created from a design pattern corresponding to a pattern to be formed on a substrate as pattern transfer information;
comparing the design pattern with the transfer pattern;
classifying the pattern transfer information and the design pattern on the basis of the feature quantity obtained from the comparison;
setting a threshold value for the feature quantity;
further classifying on the basis of the threshold value the pattern transfer information and the design pattern classified on the basis of the feature quantity;
verifying whether the transfer pattern satisfies the threshold value; and
displaying the result of the verification.

15. A semiconductor device manufacturing method comprising:
acquiring information on a transfer pattern created from a design pattern corresponding to a pattern to be formed on a substrate as pattern transfer information;
comparing the design pattern with the transfer pattern;
classifying the pattern transfer information and the design pattern on the basis of the feature quantity obtained from the comparison;
setting a threshold value for the feature quantity;
further classifying on the basis of the threshold value the pattern transfer information and the design pattern classified on the basis of the feature quantity;
verifying whether the transfer pattern satisfies the threshold value;
if the transfer pattern satisfies the threshold value, forming a mask according to a mask pattern based on the design pattern; and
forming a pattern on the substrate using the mask.

16. The semiconductor device manufacturing method according to claim 15, wherein verification is conducted to see if the transfer pattern satisfies the threshold value,
if the transfer pattern does not satisfy the threshold value, a first modification of the design pattern is made so that the transfer pattern may satisfy the threshold value, and
verification is conducted to see if a first modified transfer pattern on the substrate made up of the design pattern subjected to the first modification satisfies the threshold value.

17. The semiconductor device manufacturing method according to claim 16, wherein the first verification subjects the design pattern to proximity correction (PC).

18. The semiconductor device manufacturing method according to claim 16, wherein verification is conducted to see if the first modified transfer pattern satisfies the threshold value, and
if the first modified transfer pattern does not satisfy the threshold value, a second modification of the design pattern subjected to the first modification is made so that the first modified transfer pattern may satisfy the threshold value.

19. The semiconductor device manufacturing method according to claim 18, wherein the second modification causes a pattern to be added to, deleted from, or moved in the design pattern subjected to the first modification.

20. The semiconductor device manufacturing method according to claim 15, wherein, before verification is conducted to see if the transfer pattern satisfies the threshold value, the layout of the design pattern is changed on the basis of information on a defect included in the design pattern, and
verification is conducted to see if a critical area is included in the design pattern whose layout has been changed.
